(19) United States
(12) Patent Application Publication
(10) Pub. No.: US 2014/0064886 A1
(43) Pub. Date: Mar. 6, 2014

(54) SYSTEM, ARCHITECTURE AND METHOD FOR SIMULTANEOUS TRANSFER AND PROCESS OF SUBSTRATES

(71) Applicant: ORBOTECH LT SOLAR, LLC., San Jose, CA (US)

(72) Inventor: Masato Toshima, Sunnyvale, CA (US)

(73) Assignee: ORBOTECH LT SOLAR, LLC., San Jose, CA (US)

(21) Appl. No.: 13/972,282

(22) Filed: Aug. 21, 2013

Related U.S. Application Data
(60) Provisional application No. 61/695,255, filed on Aug. 30, 2012.

(51) Int. Cl. H01L 21/677

(52) U.S. Cl. CPC H01L 21/677
USPC 414/221

(57) ABSTRACT

An architecture for substrate processing system wherein a group of several substrates are transferred simultaneously and processed simultaneously. Robot arm is used to transfer the substrates using a substrate hanger attached to the end thereof. The hanger is configured to slide above the substrates and pick up the substrates using hanger extensions that slide under the substrates and hold the substrates at their peripheral edge. By hanging the substrates from above, no regards to the position of lift pins is necessary. Also, by constructing the hanger to be symmetrical, the hanger motion is strictly linear and need not rotate. This saves transfer time and avoids collision with lift pins. Also, the symmetry and linear motion of the hanger maintains the substrates at the same relative position throughout the transfer and processing sequence.

### RELATED CASES

This Application claims priority benefit from U.S. Provisional Application No. 61/695,255, filed on Aug. 30, 2012, the entire disclosure of which is incorporated herein by reference.

### BACKGROUND

1. Field

The subject invention relates to processing of substrates, such as semiconductor wafers, solar cell substrates, etc.

2. Related art

In the processing of substrates, there are different system architectures and different ways of moving the substrates through the system, e.g., robot arms, conveyors, levitation, etc. Embodiments of this invention relate to systems wherein robot arms move the substrates. In traditional semiconductor processing systems, robot arms move wafers one at a time. Some systems, such as the Producer® marketed by Applied Materials of Santa Clara, have robot that moves two wafers at a time. However, many system architectures have several processing chambers, and the transfer time of the robot slows the throughput of the system.

FIG. 1 illustrates a prior art system designed to operate with processing chambers, 100a and 100b, each of which processes four substrate simultaneously, thereby referred to herein as quad-chambers. The system has a front end section 105 (sometimes referred to in the art as “mini-environment”), to which four substrate cassettes or FOUPs 110 are attached. Track robot 115 transfers substrates between the cassettes and quad loadlock 120. A double-articulated arm robot 125 (e.g. a double SCARA robot arm) is positioned inside the mainframe (also referred to as transfer chamber) 130 and transfers substrates between loadlock 120 and processing chambers 100a and 100b. Each of the arms of robot 125 is made to support two substrates simultaneously, using elongated end effector 135. As is well known, the end effector is basically a flat piece of metal, somewhat similar to a blade of a knife, that comes under the substrate and lifts the substrate from underneath. Therefore, in programming the motion of the robot arm, one must take into account the lift pins that hold the substrate, so as not to cause the end effector to collide with the lift pins, as such a collision can lead to a catastrophic failure.

As can be appreciated, due to the required rotation of the articulated arm robot, the mainframe 130 must be built large enough to accommodate the full motion of the arm. The large size of the mainframe increases the overall cost of ownership of the system, as it requires a larger footprint inside the cleanroom. Also, since the arms pivot about one point inside the mainframe, the processing chambers must be attached to the mainframe in alignment with the pivot point of the arm. Consequently, one cannot install two chambers side-by-side. Rather, one chamber must be installed on each side of the mainframe. This further increases the footprint of the system.

Note also that the prior art system shown in FIG. 1 has only one loadlock serving two chambers. This can lead to a bottleneck at the loadlock, starving the chambers for substrates. Adding another quad loadlock in this architecture will not help, since the robot can only serve one quad chamber at a time.

FIG. 2 illustrates another type of robot arm, 225, which pivots about point 240 (shown in different positions using dashed-lines). The end effector 235 is attached to a rotational pivot 245 at the end of the arm 225. In this manner, as the arm rotates towards the chamber, the end effector rotates as shown by the curves arrow, so as to avoid the lift pins and align with the substrate from underneath. This robot is designed for supporting only a single substrate at a time. As shown in FIG. 3, such a robot cannot be fitted with a larger end effector to support several substrates simultaneously. That is, as shown in FIG. 3, for the robot arm to enter and exit the chamber, the end effector must be rotated, as shown by the curved arrow. As the end effector would be rotated, there is no way to avoid a collision with the lift pins. Thus, the robot arm shown in FIG. 2 is limited to lifting a single substrate at a time.

What is needed is a simpler architecture that enables lifting and transporting several substrates simultaneously. Also, it would be beneficial to have a robot arm that does not require a large mainframe, such that the footprint of the entire system can be reduced.

### SUMMARY

The following summary is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Embodiments of the invention provide architectures that are simpler and cheaper to manufacture and maintain. The architectures according to disclosed embodiments also have much smaller footprint from prior art architectures, although they enable transfer and processing of four (2×2) or nine (3×3) substrates simultaneously. Moreover, embodiments of the invention enable mounting of processing chambers side-by-side onto the mainframe.

According to one example, a substrate processing system configured for simultaneously transferring a group of substrates is provided, comprising: at least one loadlock capable of housing therein the group of substrates simultaneously; a transfer chamber attached to one side of the loadlock and having a robot arm mounted therein, the robot arm having substrate hanger at a distal end thereof, the hanger configured for hanging the group of substrates simultaneously; and a processing chamber attached to one side of the transfer chamber, the processing chamber configured for receiving and processing the group of substrates simultaneously.

Additionally, disclosed embodiments provide improved robot arm architectures. According to one example, a robot arm for transferring flat substrates is provided, comprising: an upper arm having a proximal end rotatably mounted onto a first pivot point; a forearm rotatably having a proximal end mounted onto a second pivot point, the second pivot point configured onto distal end of the upper arm; and a substrate hanger rotatably mounted onto a third pivot point, the third pivot point configured onto distal end of the forearm. The substrate hanger is configured for sliding over the substrates and having hanging extensions configured to slide under the substrates and hang the substrates from the periphery of each substrate, such that the substrates hang below the robot arm; and the upper arm, the forearm and the substrate hanger are coupled to electrical motors to be rotated independently but in coordination so as to impart linear transfer motion to the substrate hanger, as well as other designated trajectory. The substrate hanger is configured for lifting four substrates simultaneously. The substrate hanger is symmetrical along an axis passing through the third pivot point, the axis being orthogonal to the direction of the linear transfer motion. The substrate hanger is mounted onto the third pivot point at the bottom of the distal end of the forearm thereby hanging below the forearm.

In one embodiment a substrate processing system is configured for simultaneously transferring and processing a group of substrates, the system comprising: at least one loadlock capable of housing therein the group of substrates simultaneously; a transfer chamber attached to one side of the loadlock and having a robot arm mounted therein, the robot arm having substrate hanger rotattably mounted to a pivot point located at a distal end of the robot arm, the hanger configured for hanging the group of substrates simultaneously; a processing chamber attached to one side of the transfer chamber, the processing chamber configured for receiving and processing the group of substrates simultaneously; and, wherein the substrate hanger is symmetrical along an axis passing through the pivot point. The robot arm has three degrees of rotational freedom, and wherein the robot arm is energized to move the substrate hanger is a linear transfer motion, as well as other designated trajectory. The substrate hanger is configured for sliding over the substrates and having hanging extensions configured to slide under the substrates and hang the substrates from the periphery of each substrate, such that the substrates hang below the robot arm.

According to further embodiments, a substrate processing system is provided, comprising: a loadlock chamber having an entry slit and an exit slit positioned across from the entry slit; a processing chamber having an entry slit; a transfer chamber attached on one side to the loadlock chamber and on opposite side to the processing chamber, the transfer chamber having an entry slit overlapping the exit slit of the loadlock chamber, the transfer chamber further having exit slit overlapping the entry slit of the processing chamber; a first gate valve provided to selectively seal the entry slit of the loadlock chamber; a second gate valve provided to selectively seal the exit slit of the loadlock chamber; a third gate valve provided to selectively seal the entry slit of the processing chamber; and, a transfer robot provided inside the transfer chamber, the transfer robot comprising a substrate hanger configured for holding a plurality of substrates simultaneously, the transfer robot configured to exchange substrates between the loadlock chamber and the processing chamber by linearly translating the substrate hanger without imparting any rotational motion to the substrate hanger.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 illustrates a prior art system designed to operate with semiconductor substrates processing chambers.

FIG. 2 illustrates one type of robot arm according to the prior art.

FIG. 3 is a close-up of the end effector of the robot of FIG. 2.

FIG. 4 illustrates an embodiment of the invention, using the same scale as that of FIG. 1.

FIG. 5 is a close-up of the loadlock and the robot transfer chamber of FIG. 4.

FIG. 5A is a cross-section along lines A-A of FIG. 5.

FIG. 6A is a top view of a robot arm according to one embodiment, while FIG. 6B is a side view of the arm of FIG. 6A.

FIG. 7 is a top view of an embodiment having a single loadlock, single transfer robot arm, and single processing chamber.

FIG. 8 is a top view of an embodiment having a dual loadlocks, dual transfer robot arms, and dual processing chambers, and having lift stations in the loadlocks and transfer chambers.

FIGS. 8A and 8B illustrate a cross-section along lines A-A of FIG. 8 in two different processing times.

FIGS. 8C-8E illustrate a cross-section along lines B-B of FIG. 8 in different processing times.

FIGS. 8F-8G illustrate a cross-section along lines C-C of FIG. 8 in different processing times.

FIG. 9 illustrates an embodiment having one track robot having dual-arms, one above the other, located in the mini-environment to load the loadlock.

FIG. 10 is a top view of an embodiment of the system, illustrating the process of exchanging wafers between the FOUPs and the processing chambers.

FIG. 11 is a top view of another embodiment, which utilizes an innovative frog-leg robot that requires no rotation for substrate exchange.

FIG. 12 is a cross-section along lines A-A of FIG. 11.

FIG. 13 is a cross-section along lines B-B of FIG. 11.

FIG. 14 is a top view of the atmospheric robot and substrate shelves according to one embodiment.

FIG. 15 is a cross-section along lines C-C of FIG. 11.

FIGS. 16A and 16B are graphical time-charts illustrating the timing difference between having a double-decker hanger (FIG. 16A) and a single level hanger (FIG. 16B).

FIGS. 17A and 17B are graphical time-charts illustrating the timing difference between a conventional ATM robot having no buffer storage (FIG. 17A) and an ATM robot with internal storage (FIG. 17B).

FIGS. 18-1 to 18-12 illustrate loading/unloading sequence in an embodiment having a single-level hanger.

FIGS. 19-1 to 19-18 illustrate loading/unloading sequence in an embodiment having a dual-level hanger.

FIG. 20 illustrates another embodiment of the atmospheric robot with storage shelves, while FIGS. 20-1 to 20-6 illustrate operation of the ATM robot.

### DETAILED DESCRIPTION

Various features and advantages of the invention will become more apparent from the embodiments described below. In each of the embodiments, various elements, such as robot arms, transfer chambers, processing chambers, etc., are described. These elements may be interchangeable among the various embodiments and to generate further embodiments not specifically described and/or illustrated herein.

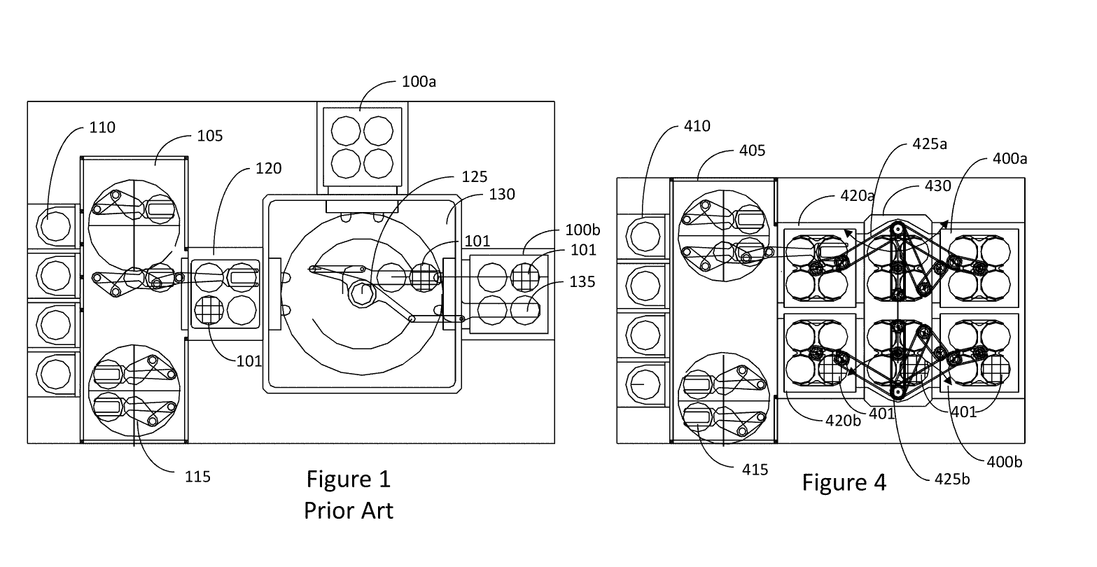

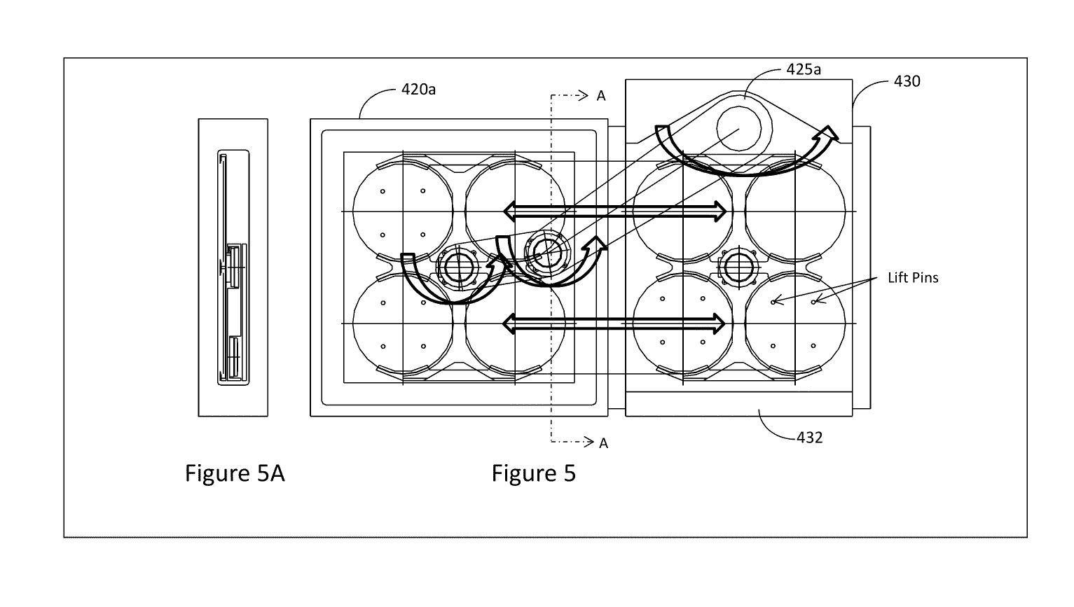

FIG. 4 illustrates an embodiment of the invention, using the same scale as that of FIG. 1, while FIG. 5 is a close-up of the loadlock and the robot transfer chamber. FIG. 5A is a cross-section along lines A-A of FIG. 5. As can be seen, the footprint of the system according to the embodiment of FIG. 4 is much smaller than that of FIG. 1. As illustrates in FIG. 4, two quad loadlocks 420a and 420b are attached to one side of mainframe (transfer chamber) 430, side-by-side. Note that these loadlocks are of the same size and can be of the same design as those shown in FIG. 1, and are drawn to the same scale as in FIG. 1. Yet, since two are attached side-by-side, they enable faster throughput with reduced footprint. The track robot 415 inside front end 405 can now feed two loadlocks. In this respect, the reference to loadlock in this disclosure is inline with standard terminology of a chamber used to transfer substrates between atmospheric and vacuum environments. Thus, while mainframe 430 is kept in vacuum, front end 405 is kept in atmospheric environment.

In the embodiment of FIG. 4, the two quad loadlocks 420a and 420b are situated such that each is serving a respective quad processing chamber 400a or 400b. Two robot arms 425a and 425b are provided inside the mainframe 430, each transferring substrate between one loadlock and its respective processing chamber (each arm is shown in multiple positions for better illustrating the motion of each arm). However, the structure of each of the robot arms is much simpler than a prior art arm, since, among others, it does not require coaxial rotation. Since the quad chambers and the loadlocks can be placed side by side using the architecture of this embodiment, the footprint of the entire system is drastically reduced as compared to prior art.

In the embodiment of FIG. 4, robot 415 inside the front-end 405 takes four fresh substrates from the FOUPs 410 and places them inside the loadlock 420a, and does the same for loadlock 420b. The loadlocks 420a and 420b are then pumped to achieve the desired vacuum level. Once the desired vacuum level is achieved, robot 425a transfers the four fresh substrates from loadlock 420a into the respective processing chamber 400a, and robot 425b transfers the four substrates into the respective processing chamber 400b. During that time, robot 415 transfers the next batch of fresh substrates into loadlocks 420a and 420b. Once processing is completed, robots 425a and 425b remove the processed substrates from their respective processing chambers 400a and 400b and, according to one embodiment, place them in the respective loadlocks, 420a and 420b, and then take the next batch of substrates from the respective loadlock and insert them into the respective processing chamber for processing.

Alternatively, according to another embodiment mainframe 430 also serves as a buffer station. Specifically, once processing is completed, robot arms 425a and 425b remove the processed substrates and place them on waiting positions, e.g., movable or stationary lift pins, positioned inside the mainframe 430. Each of robots 425a and 425b then removes the fresh substrates from the respective loadlocks and place them inside the respective processing chamber 400a and 400b. the vacuum doors separating the processing chambers from the mainframe 430 can be closed and processing inside processing chambers 400a and 400b may commence. The robot arms 425a and 425b can then move the processed wafers from the mainframe 430 to the respective loadlocks 420a and 420b. Robot 415 then removes the processed substrates from the loadlocks and place them in the FOUPs, and then loads the next batch of fresh substrates into the loadlocks. In this manner, eight substrates can be transferred and processed simultaneously.

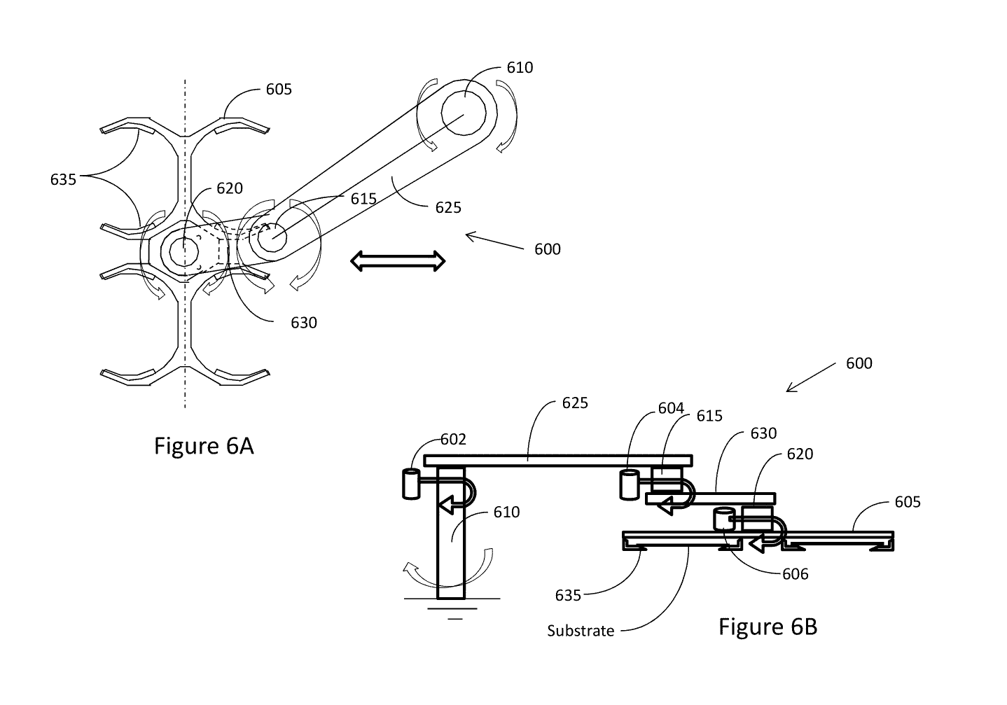

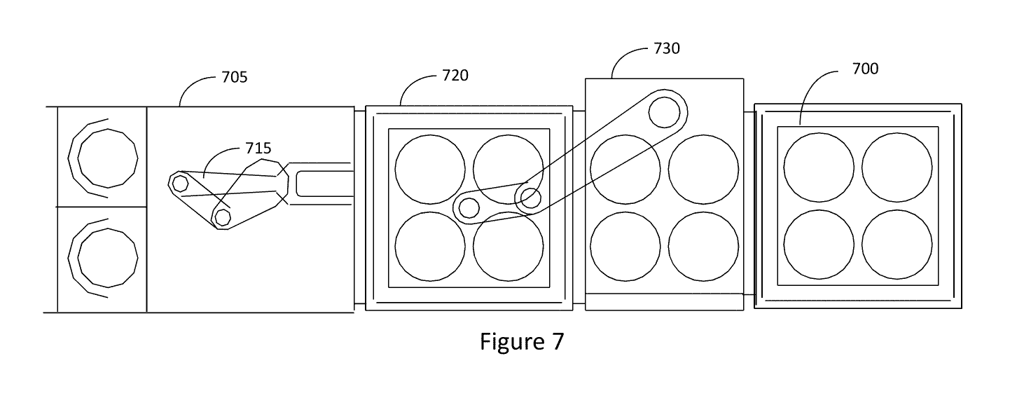

One feature employed in the architecture of FIG. 4, is that the robot arm comes from above the substrates and slides a hanger to hang the four wafers simultaneously. That is, as opposed to the prior art robot arms that use end effector that holds the substrate from underneath, robot arms 425a and 425b utilize hangers in which the wafers hang, so that the arm comes over from above the substrates. Consequently, the issue of trying to avoid hitting the lift pins, as in the prior art, does not exist. The lift pins can be designed arbitrarily and the robot will lift all wafers without consideration of the lift pins. This is illustrated and further explained with reference to FIGS. 5, 5A, 6A and 6B, which illustrate the architecture of the robot arm according to this embodiment.

FIG. 5 illustrates a close-up of robot arm 425a, together with part of main frame 430 and the respective loadlock 420a. As shown by the curved arrows, as the elements of arm 425a rotate in coordination, arm 425a moves four wafers simultaneously in a linear motion—demonstrated by the straight double-headed arrows. As the saying goes, the shortest distance between two points is a straight line, and this embodiment enables moving the substrates in a straight line from the processing chamber to the loadlock without any rotation or curved trajectory. Moreover, when mainframe 430 serves as a buffer station, four processed wafers can be placed on lift pins in the mainframe 430, and the robot arm can move four fresh wafers over the processed wafers and into the processing chamber. For example, the lift pins may be movable such that after placing the wafers on the lift pins, the lift pins would lower to enable free motion of the robot arm 425a with fresh substrates over the processed wafers and into the processing chamber.

FIG. 5 also illustrates an optional partition 432 provided in the middle of mainframe 430. Partition 432 may be included when it is desirable to separate the environment of robot arms 425a and 425b. Moreover, If only a single processing chamber is needed, then the system may be fabricated using a single loadlock and a single processing chamber, using a mainframe 430 that has a single robot arm, as shown in FIG. 5.

An embodiment of the robot arm with a hanger will now be described in further details. As illustrated in FIGS. 6A and 6B, robot arm 600 has a quad wafer hanger 605 at the end thereof, rather than the conventional end effector. The arm 600 has three degrees of freedom in rotation: shoulder, elbow, and wrist, about pivots 610, 615, and 620, respectively. That is, upper arm 625 rotates about pivot 610, forearm 630 rotates about pivot 615, which is mounted onto the distal end of the arm 625, and the quad hanger 605 rotates about pivot 620, which is provided at the distal end of the forearm 630, i.e., the wrist. Each of these pivot points is coupled to a motor to be rotated independently but in coordination with the other pivot points, as shown schematically by motor 602, 604 and 606 in FIG. 6B. This enables to get four wafers in and out of the chamber simultaneously, without concern for lift pins design. Moreover, using these three degrees of rotation with active motor control on each pivot point, the quad wafers can be moved in linear fashion, as shown by the double-headed arrow. Other designated trajectories are also possible with the proper operation of the active motor control.

That is, as shown in FIG. 6B, unlike the prior art, the robot arm does not move under the substrate, but rather over the substrates. Also, rather than having an end effector lifting the substrate from underneath, a quad substrate hanger 605 with clips or hanging extensions 635 slides under and hangs the substrates from the periphery of each substrate, such that the substrates hang below the robot arm. Consequently, four wafers can be transported into and out of the chamber without regards to the lift pins design, since there's no end effector that might collide with the lift pins.

Another feature of the hanger is that it is configured to be symmetrical along an axis (shown by the dash-dot line) passing through the pivot point 620, wherein the symmetry axis is orthogonal to the direction of the linear transfer motion shown by the double-headed arrow. The benefit of this symmetry is that the right side and the left side of the hanger shown in FIG. 6A are the same. Thus, there is no “front side” or “rear side” to the hanger so that it need not be rotated for wafer exchange. To illustrate, using standard end effector, such as shown in FIG. 1, when the robot removes the wafers from the processing chamber 100b, in order to deliver these wafers to the loadlock 120, the robot must rotate 180° so that the front of the end effector is aligned with the loadlock. Conversely, when the robot 425a, shown in FIG. 4, removes the substrates from processing chamber 400a, it does not need to rotate the hanger in order to deliver these wafers to the loadlock 420a. Rather, since the hanger is symmetrical, the wafers that were in the front inside the processing chamber end up in the front inside the loadlock chamber, so that no rotation is necessary.

Another feature of using the symmetrical hanger with linear transfer motion is that the wafers always remain in their relative position. To illustrate, wafer 101 has been cross-hatched in FIG. 1 and wafer 401 has been cross-hatched in FIG. 4. As can be seen in FIG. 1, when wafer 101 is removed from the processing chamber 100b and delivered to the loadlock 120, due to the required rotation of robot 125 the wafer 101 ends up in a different relative position to where it was inside the processing chamber. Conversely, when wafer 401 is removed from the processing chamber 400b, since the hanger is not rotated, the wafer 401 ends up at the same relative position inside the loadlock 420b as where it was inside the processing chamber 400b.

Another problem introduced by conventional end-effector design is shifting of wafers during the rotational motion. That is, since the end effector cannot use vacuum suction to secure the wafers (the entire transfer chamber is in vacuum), the wafers tend to slip during the rotation motion of the robot arm to thereby cause rotational alignment shift. Consequently, rotation of the conventional robot has to be performed slowly, thus leading to elongated wafer loading/unloading time.

FIG. 7 illustrates an embodiment of the invention, wherein only a single quad processing chamber 700 is used. As illustrates in FIG. 7, one quad loadlock 720 is attached to one side of mainframe 730, wherein the quad robot arm is mounted. The track robot 715 inside front end 705 feeds the single loadlock 720.

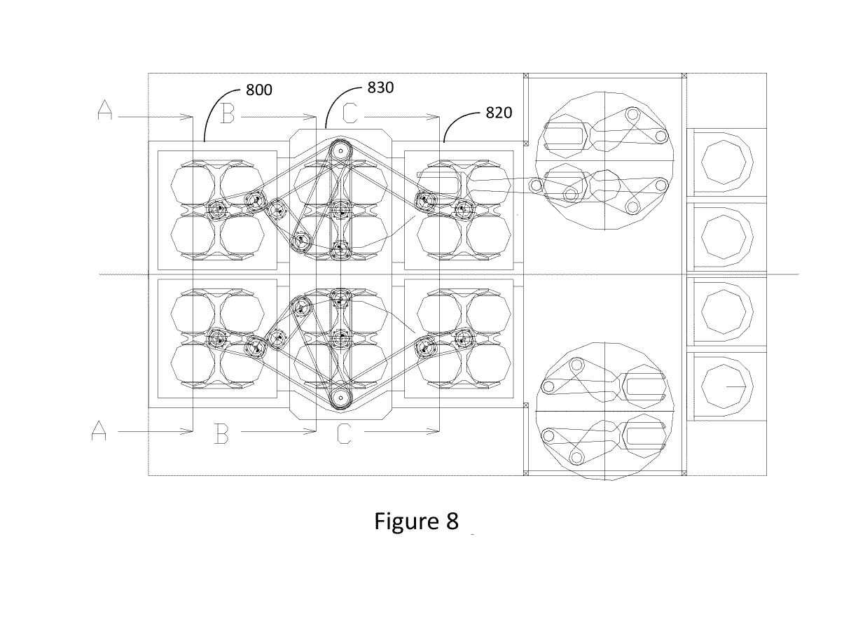

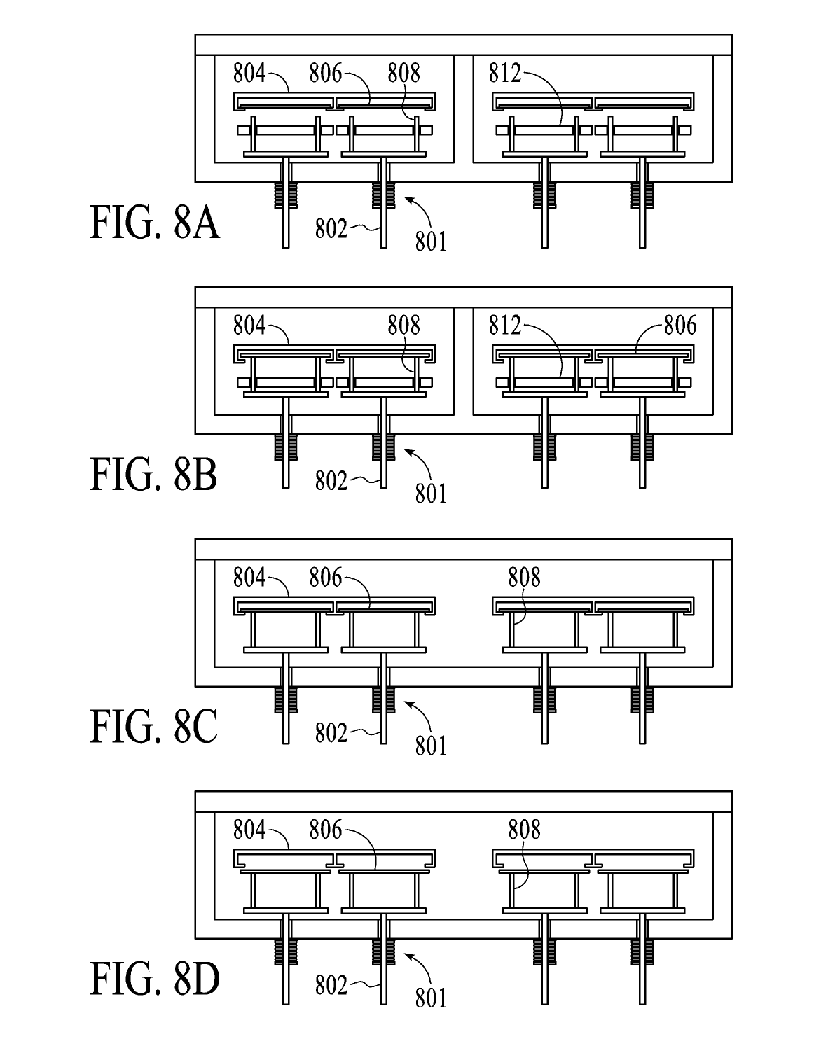

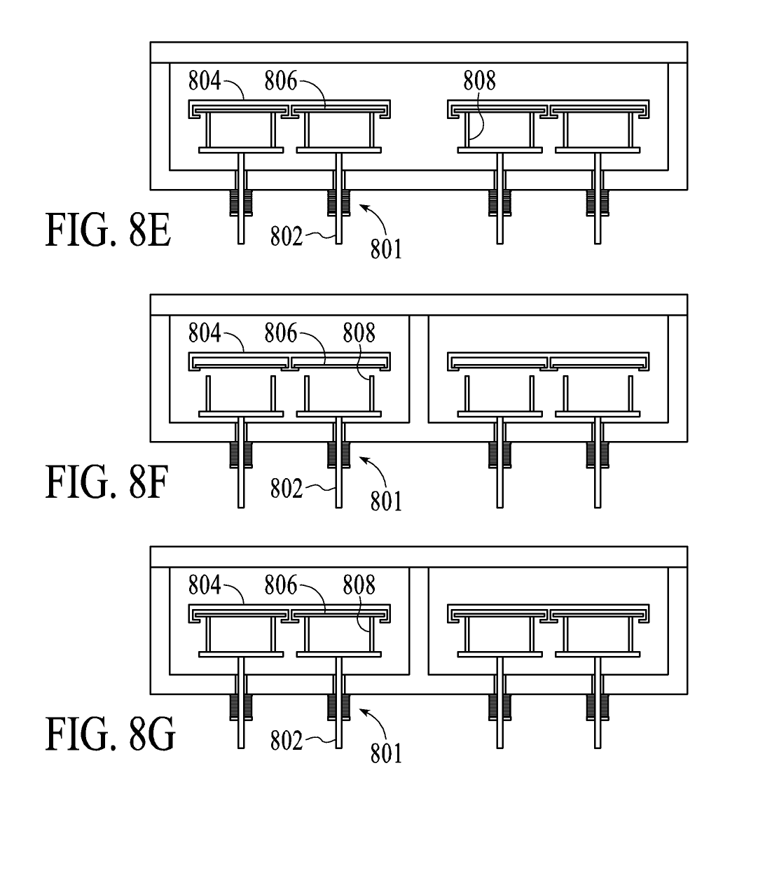

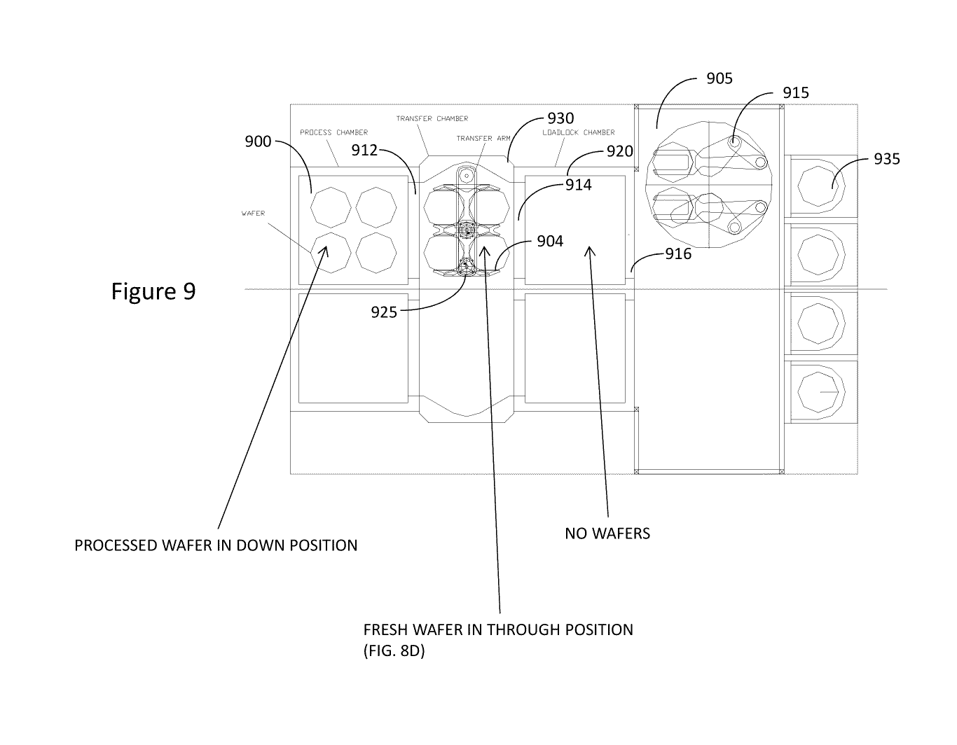

FIG. 8 illustrates another embodiment wherein three wafer lifter modules (e.g., mechanized lift pins) are provided, one in the process chamber 800, a second in the loadlock chamber 820, and third one in the transfer chamber 830. That is, in this embodiment, a wafer lifter is also fitted inside the transfer chamber where the robot arm resides. Note that in this drawing the mini-environment is depicted on the right-hand side of the page, i.e., the system is shown rotated 180° from what is shown in FIG. 4. This, of course, has no effect on the design and operation of the system, but simply depends on the customer's particular installation of the system in the fab.

FIGS. 8A-8G illustrate the cross-sections noted as A-A, B-B and C-C in FIG. 8. FIG. 8A illustrates a cross-section inside the processing chamber 800, wherein wafer lifter module 801 is used to exchange wafers. Wafer lift module 801 includes lifting mechanism 802 which lifts and lowers lift pins 808, passing in holes provided in susceptor 812. Susceptor 812 may include heater, cooler, RF electrode, chucking electrode, etc., depending on the processing performed inside the processing chamber 800. In the instance of time illustrated in FIG. 8A, wafers 806 are positioned on hanger 804, e.g., when the robot arm delivers new wafers for processing or removes processed wafers. While not shown here, hanger 804 is attached to the end of robot arm, as shown in previous embodiments. The wafer lifter module is shown in intermediate position, i.e., preparing to remove the wafers 806 from the hanger 804, or just after delivering wafers 806 to the hanger 804. FIG. 8B illustrates a cross-section in time wherein the lifter module 801 is lifting the wafers 806 from the hanger 804, e.g., for removing fresh wafers 806 from the hanger 804 and place them on susceptor 812, or for dropping processed wafers 806 which were previously removed by the lifter module from the susceptor 812.

FIGS. 8C-8E illustrate cross-section inside the transfer chamber 830, wherein wafer lifter module 801 is used to exchange wafers or to perform the function of a buffer station while the robot arm exchanges wafers. Note that in this example, no partition is provided between the left and right parts of the transfer station, although in other embodiments it is possible to provide partition, such that the two sides of the system are completely isolated from each other. FIG. 8C illustrates the point in time wherein the wafers 806 are positioned on the hangers 804. FIG. 8D illustrates the point in time wherein the wafers 806 are positioned on the lift pins 808 at an elevation below the level of the hanger, such that this position can be used as a buffer station. In this position the hanger may freely move above the wafers without collision. For example, the robot arm may place processed wafers on the lift pins as shown in FIG. 8D, then the arm may remove fresh wafers from the loadlock and place them inside the processing chamber. The entry valve to the processing chamber may then be closed so that processing may commence, while the arm may then pick up the processed wafers from the buffer position on pins 808 and deliver them to the loadlock. FIG. 8E illustrates the point in time wherein the wafers 806 are positioned on the lift pins 808 at a level either just after removing the wafers from the hanger 804 or just prior to delivering the wafers to the hanger 804.

FIGS. 8F-8G illustrate cross-section inside the loadlock chamber 820, wherein wafer lifter module 801 is used to exchange wafers with the hanger. Note that in this example, a partition is provided between the left and right loadlocks, although in other embodiments it is possible to remove the partition, such that the two sides of the system are not completely isolated from each other. In such a case both sides should be operated synchronously in time. In the instance of time illustrated in FIG. 8F, wafers 806 are positioned on hanger 804, e.g., when the robot arm delivers processed wafers to the loadlock or removes fresh wafers from the loadlock. The wafer lifter module is shown in intermediate position, i.e., preparing to remove the wafers 806 from the hanger 804, or just after delivering wafers 806 to the hanger 804. FIG. 8G illustrates a cross-section in time wherein the lifter module 801 is lifting the wafers 806 from the hanger 804, e.g., for loading fresh wafers 806 to the hanger 804, or for removing processed wafers 806 from the hanger.

The embodiment of FIG. 8 leads to some benefits, summarized as follows. Using only two lifter modules, i.e., no lifter module in the transfer chamber, it required two vertically stacked lift pins in the loadlock chamber, and the vertical pitch is quite large because the entire robot's forearm and upper arm must be inserted. This increased loadlock chamber volume substantially and this means vacuum pumping is suffered. Another benefit is shorter transfer time. Without the lifter in the transfer chamber, the sequence required to return the finished wafers to loadlock chamber (one of the vertically stacked shelf) and then pull out fresh wafers. However, with the lifters in the transfer chamber, pulling out fresh wafers can be done earlier so that the above transfer time is halved.

The following is an example of a sequence for transferring wafers using the embodiment of FIG. 8, wherein the initial position is illustrated in FIG. 9, wherein processing in the process chamber 900 is just completed, and wafers are ready to be removed from process chamber 900.

1. Process chamber's lifters are raised to lift the wafers, the gate valve 912 opens, and robot 925 unloads wafers from the chamber 900.

2. Robot 925 retracts to the transfer chamber 930. In the transfer chamber, there are 4 fresh wafers sitting on lift pins, and those wafers are at a far lower level than robot moving level (i.e., buffer position as illustrated in FIG. 8D), so that the robot motion does not interfere with those fresh wafers.

3. Next, process chamber's gate valve 912 closes and loadlock chamber gate valve 914 opens. The robot arm 925 further extends into loadlock chamber 920 and unloads processed wafers on lifting pins in loadlock chamber 920.

4. Now the robot comes back to the transfer chamber 930, but prior to this motion, the fresh wafers on the lift pins in the transfer chamber move up to the “lift” position, such that when the robot arm returns into the transfer chamber the fresh wafers go between hangers.

5. The fresh wafers are settled on hangers by lowering the lift pins inside the transfer chamber 930.

6. Loadlock chamber gate valve 914 closes and process chamber gate valve 912 opens, so that the robot arm 925 extends into process chamber 900 and transfers the fresh wafers to process chamber 900.

7. The process chamber gate valve 912 is then closed and processing of the fresh wafers may commence.

8. The gate valve 916 is opened and the processed wafers in the loadlock are replaced with fresh wafers from FOUP 935 by the robot 915 that is positioned in the front-end module 905.

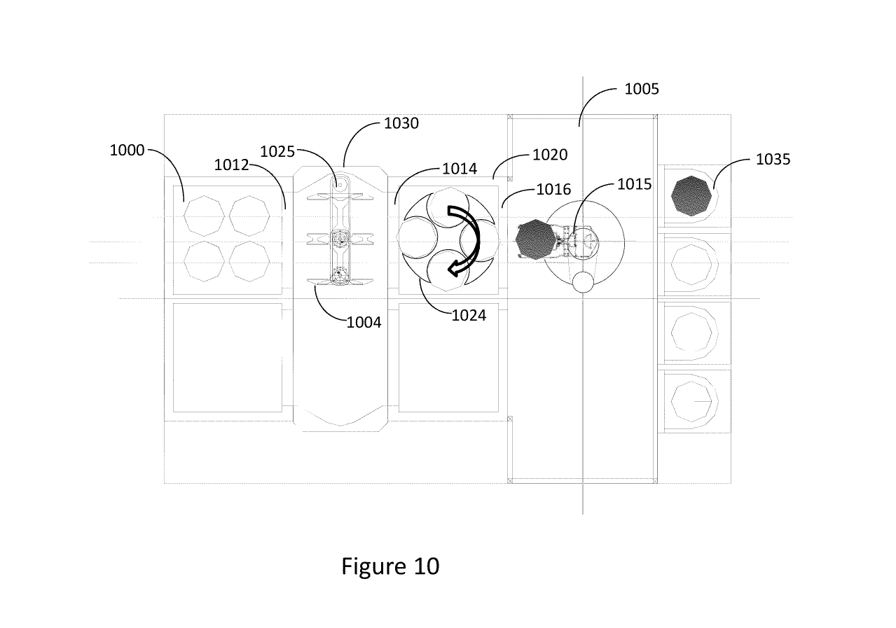

Using the above examples, the robot 915 of the front-end module needs to be able to extend deep into the loadlock in order to exchange the two wafers that are situated at the side of the loadlock that abuts the transfer chamber. On the other hand, the embodiment illustrated in FIG. 10 avoids this issue. In this embodiment, the loadlock 1020 is equipped with a rotating turntable 1024, and the robot 1015 inside the front-end module 1005 is a ‘double-decker”, meaning there are two arms, one above the other. Each of the robot arms 1015 need only to extend to the position of the wafer closest to the gate valve 1016 of front-end module 1005. Note that only one side of the system is illustrated, with the other side (being lower side in the drawings) would be axially symmetrical.

In the position shown in FIG. 10, the upper arm of the double-decker robot 1015 is supporting a fresh wafer and the lower arm is empty. Next the lower arm extends to collect processed wafer from the turntable 1024. The lower arm retracts, thereby removing the processed wafer from the turntable 1024, while the upper arm is extending to deliver the fresh wafer to the same position on the turntable 1024 where the processed wafer was just removed. The double-decker robot 1015 then move to a position in front of FOUP 1035 (which may be any of the two FOUPs illustrated for serving the upper processing chamber). The lower arm extends to deposit the processed wafer in the FOUP, while the upper arm extends to remove another fresh wafer from the FOUP. At the same time, the turntable 1024 is rotated such that when the double-decker returns, another processed wafer is positioned for removal. The process of exchanging wafers with the turntable repeats such that the turntable 1024 is filled with four fresh wafers.

The transfer arm 1025 then moves into the loadlock 1020 and unloads all four fresh wafers simultaneously. The transfer arm 1025 deposits the four fresh wafers on a lifter positioned inside the transfer chamber 1030 on lift pins positioned in buffer position. The arm 1025 then moves into the process chamber 1000 and unloads four processed wafers from the process chamber. Thereafter, transfer arm 1025 retracts into the transfer chamber 1030, so that the gate valve 1012 of the process chamber 1000 can be closed and the gate valve 1014 of the loadlock 1020 can be opened. Then, the transfer arm 1025 extends to deposit the processed wafers onto the turntable 1024. After the gate valve 1014 is closed and gate valve 1012 is opened, the arm 1025 can pick up the fresh wafers from the lifter inside transfer chamber 1030 and deliver the fresh wafers to the process chamber 1000. Thereafter the transfer arm retracts, the gate valve 1012 of the process chamber is closed, and processing of the wafers begins. At this position, the process restarts from the position shown in FIG. 10.

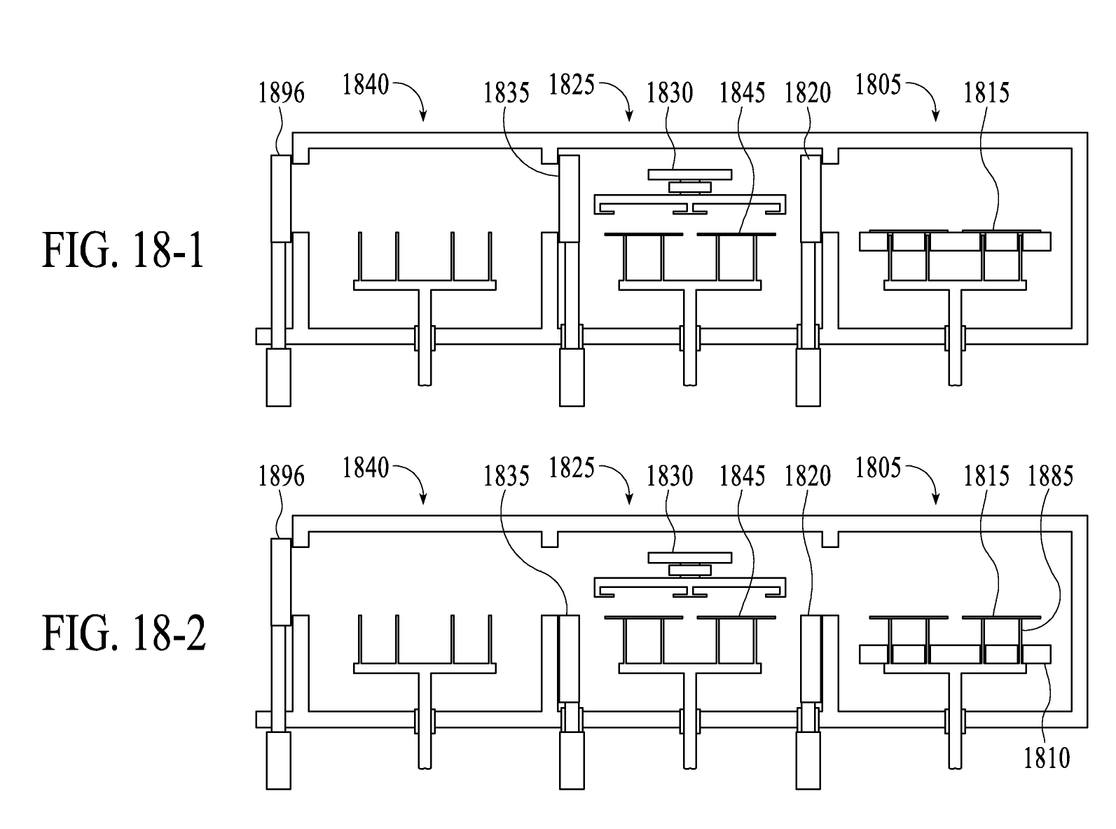

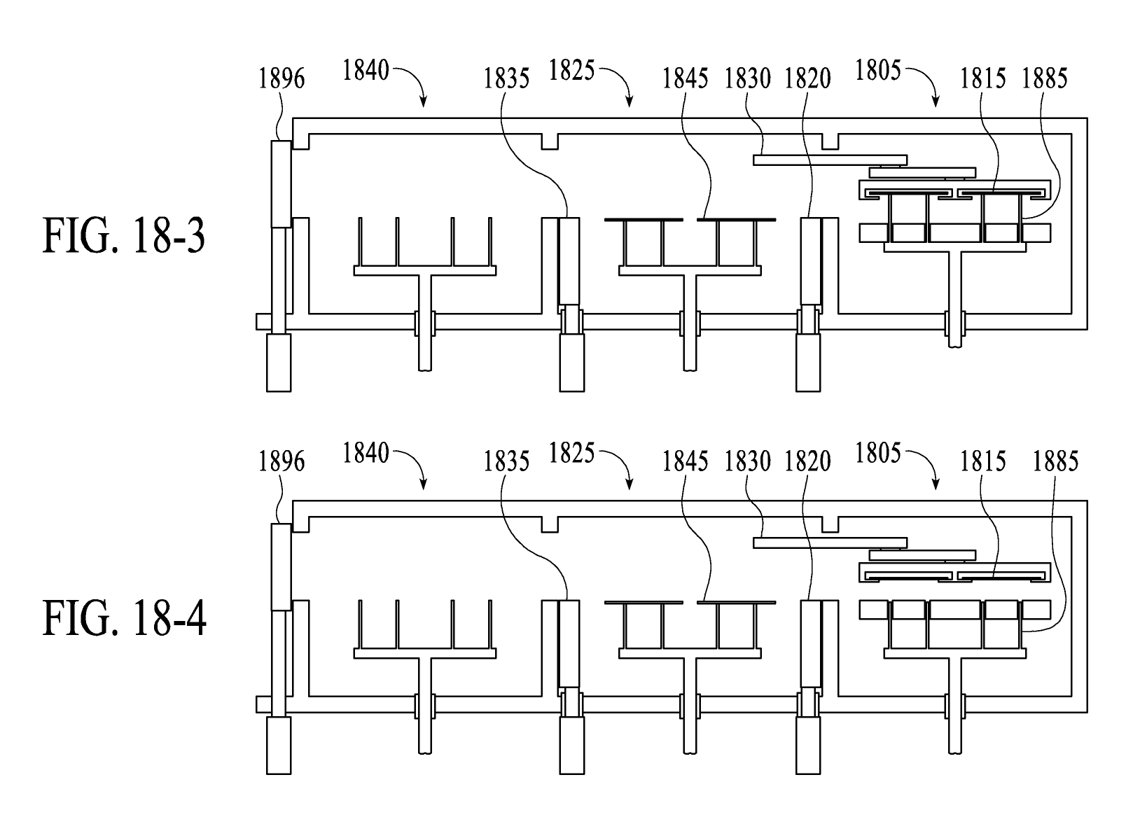

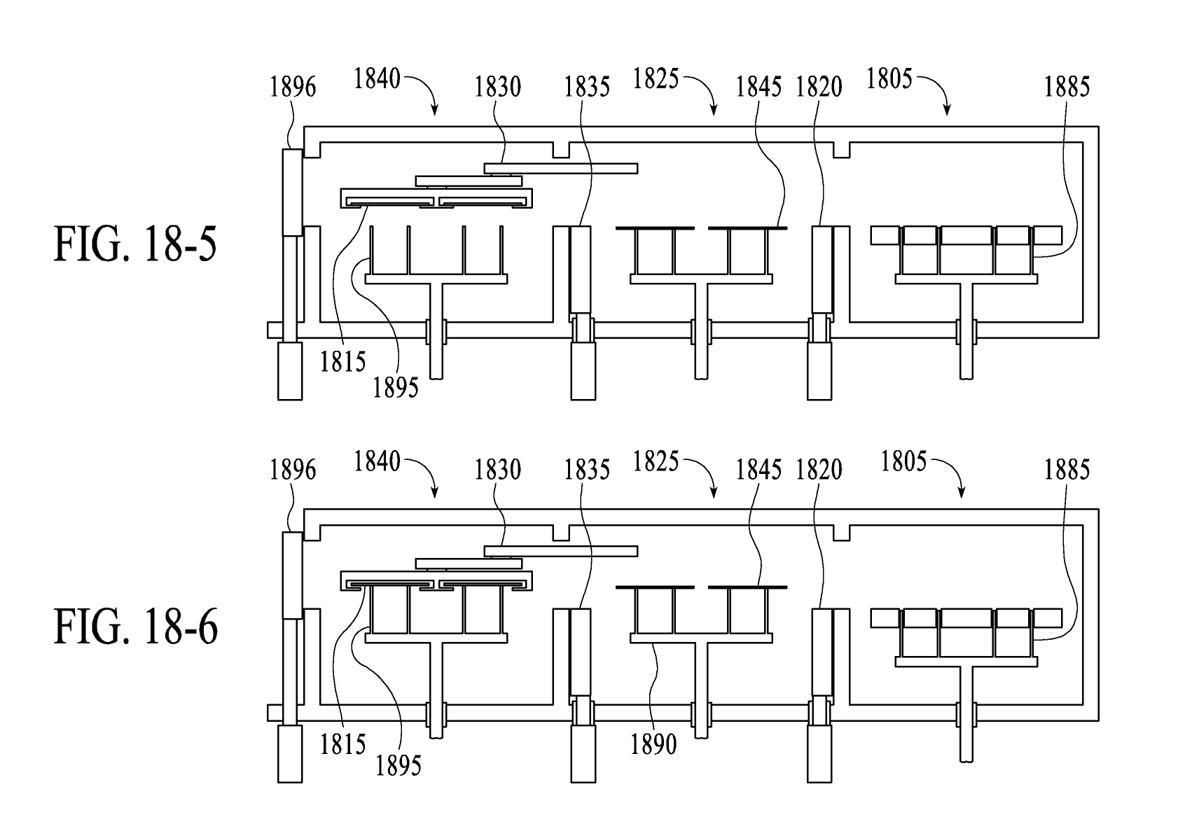

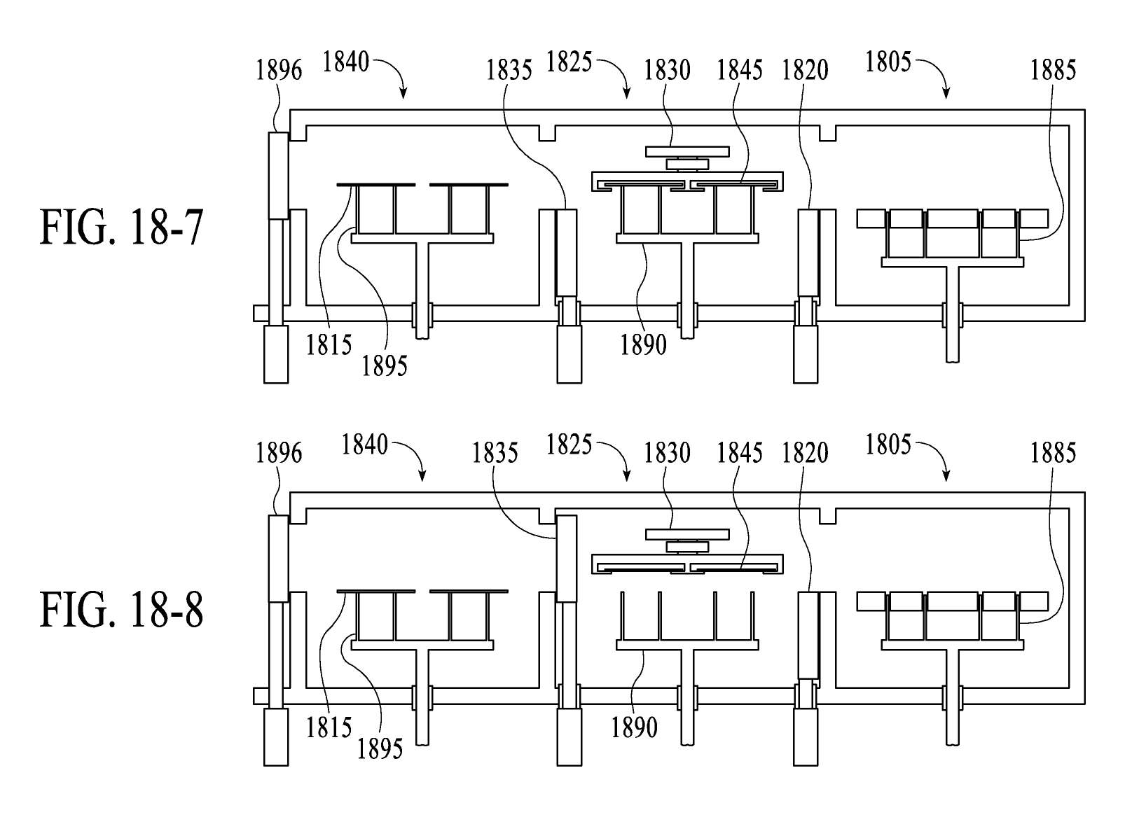

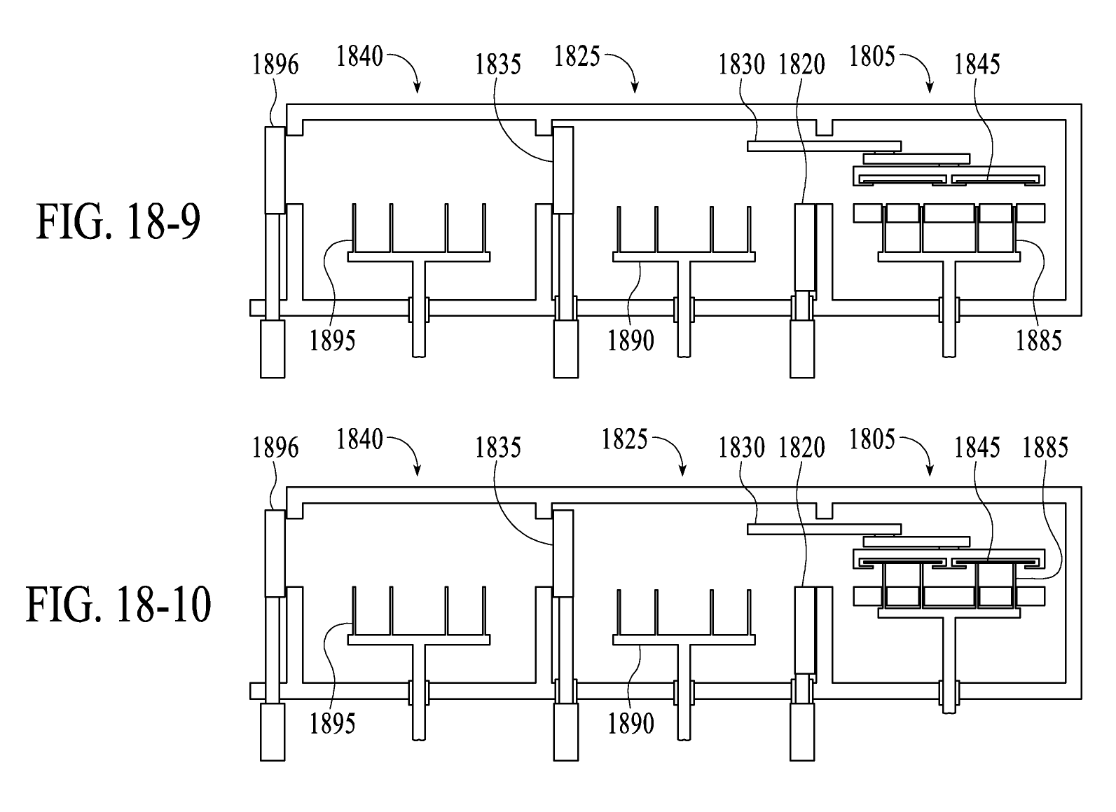

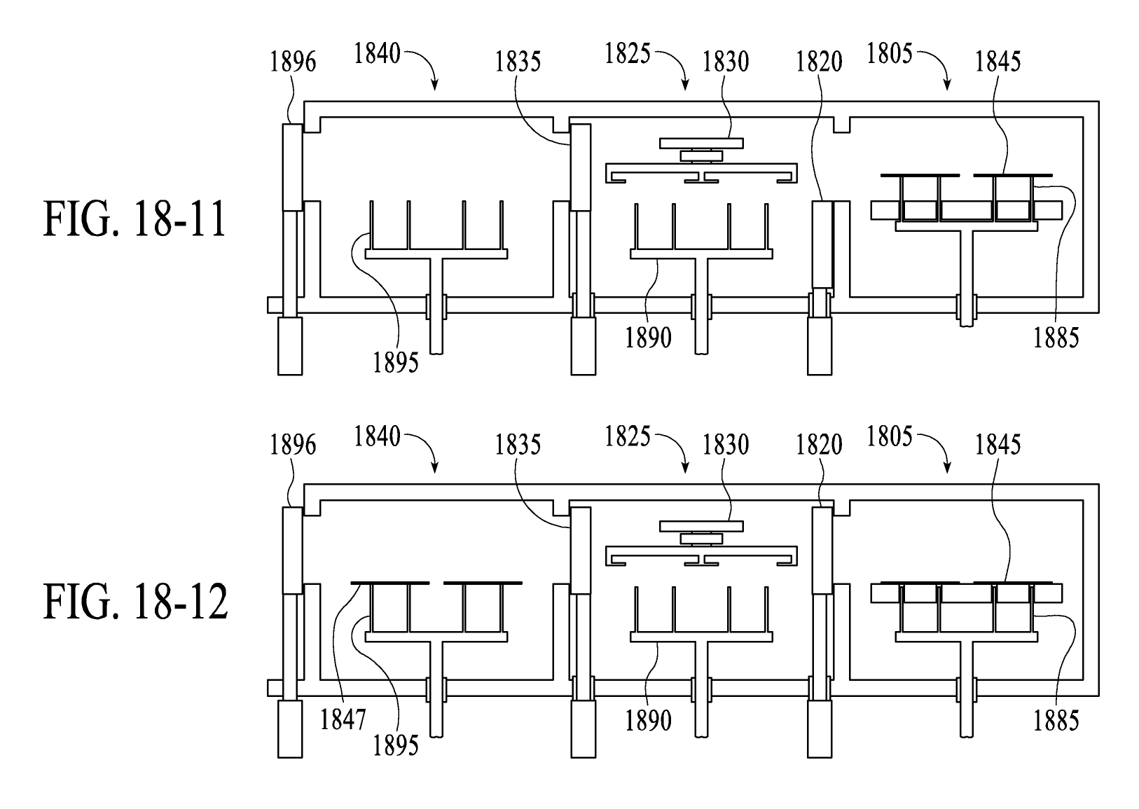

The above embodiments describe a system wherein a single robot arm (e.g., SCARA—Selective Compliance Articulated Robot Arm) is used to hold the hanger with the wafers. The description now turns to embodiments utilizing the so-called frog-leg robot. Frog leg robot utilizes two arms that are energized individually, but are connected at their wrists to a single end effector. Such robots suffer from a singularity point leading to control instability. This is described in, for example, U.S. 2010/0076601. A simple solution is to never drive the robot to the singularity point, but rather retract the arms and stop prior to the arms reaching the singularity point, rotating the arms 180° and then extending the arm. Thus, the arms are never driven above the singularity point, i.e., above the main rotation shaft. U.S. 2010/0076601 suggests adding a driving motor at the wrist position and including a synchronization module to synchronize the motion of the two wrists. Such an arrangement complicates the construction of the robot and requires a motor to be attached to the wrist, which adds weight, and thus stress, to the wrists. Moreover, adding a motor and synchronization unit to the wrist may lead to unwanted contamination when the robot is employed in a clean environment, such as in the fabrication of semiconductor devices. Additionally, when the wrist enters the processing chamber it may be heated, such that it may lead to failure or material fatigue. Finally, the motor and synchronization units at the wrist does not allow for rotation of the wrist, such that the entire robot structure must be turned in order to deliver the substrate from the processing chamber to the loadlock (see, e.g., FIG. 18 of U.S. 2010/0076601).

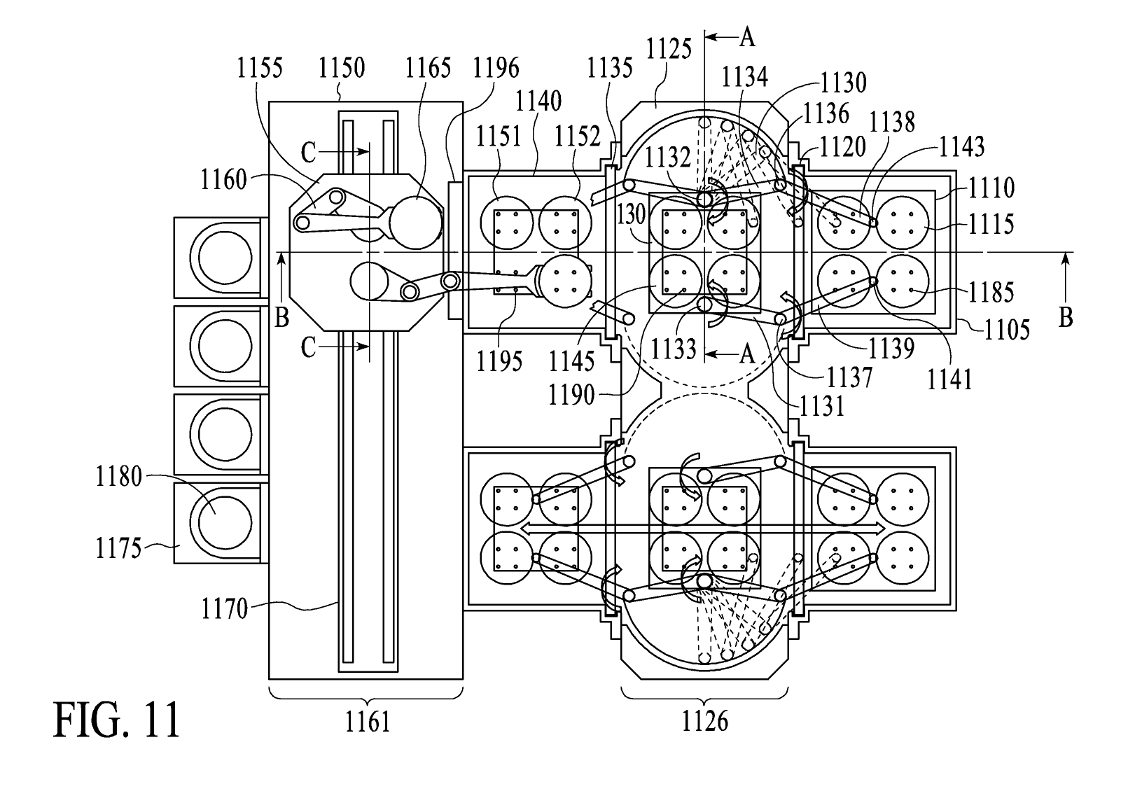

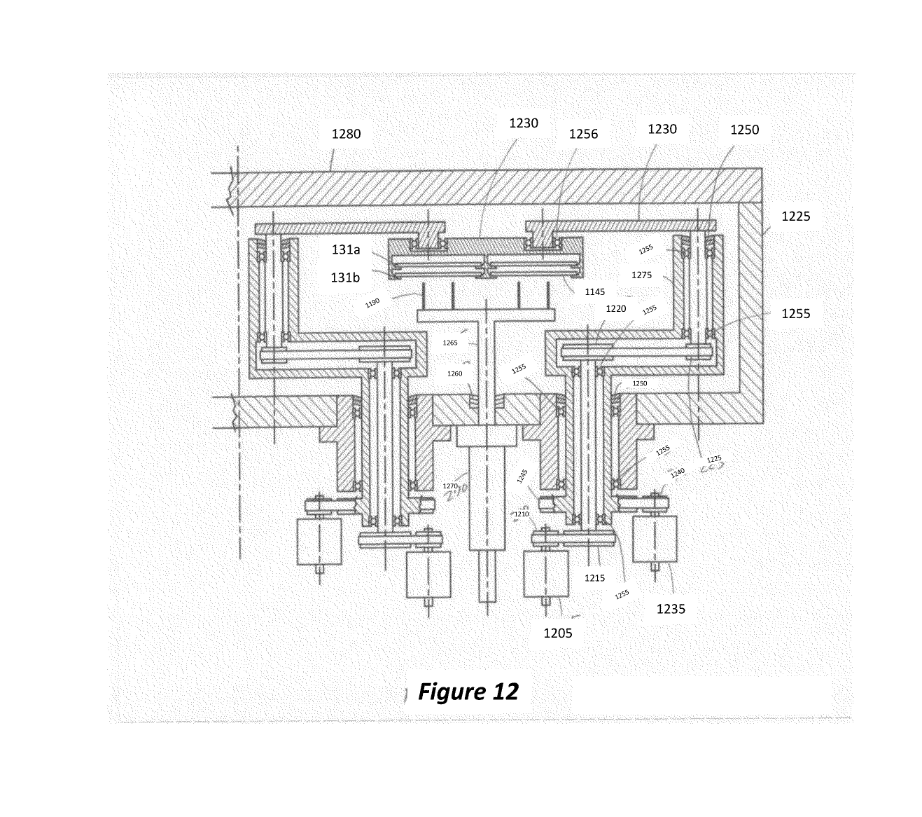

The embodiment exemplified in FIGS. 11 and 12 utilize a frog-leg robot design that avoids the singularity point problem. The system of FIG. 11 includes two processing chambers 1105, each processing four substrates 1115 simultaneously, as in the prior embodiments. The substrates may be placed on a susceptor 1110, which may include a heater, a cooler, RF electrode, and/or chucking electrode. Additionally, a lifter may be included to elevate lift pins to accept and remove substrates from the susceptor. The chamber environment is isolated by gate valve 1120.

Transfer chamber 1125 houses frog-leg robot 1130. As shown in FIG. 11, the frog-legs robot has two arms, 1134 and 1131, actively rotatable, i.e., driven, about main pivot points 1132 and 1133, respectively, using appropriate motor arrangement (shown more specifically in FIG. 12). Each of the arms has three degrees of freedom in rotation: shoulder 1132 and 1133, elbow 1136 and 1137, and wrist 1143 and 1141. Pivot points shoulder 1132 and 1133 and elbow 1136 and 1137, are mechanized, i.e., driven, while pivot points wrist 1143 and 1141 are freely rotatable and not driven. That is, upper arms 1134 and 1131 are controlled by motors to rotate about pivots 1132 and 1133, respectively, and forearms 1138 and 1139 are controlled by a separate motor to rotate about pivots 1136 and 1137, respectively. The quad hanger (shown in FIG. 12) is attached to freely rotatable pivots 1143 and 1141, which are provided at the distal end of the forearms 1138 and 1139, i.e., at the wrists. The quad hanger is configured such that it is symmetrical about the imaginary line between the connections to pivot points 1143 and 1141, i.e., the line passing through the two wrists.

One advantage of this design is that it completely avoids the need to rotate the entire robot structure, as is done in prior art frog-leg robot. Instead, in order to move wafers between the processing chamber 1105 and loadlock 1140 only a linear motion of the hanger is required, as illustrated by the double headed arrow on the bottom part of FIG. 11. Such a transfer required a 180° rotation of a conventional frog-leg robot. However, using a 180° rotation would have required a much larger transfer chamber than what is needed for the robot of FIG. 11.

The transfer chamber 1125 is isolated from loadlock 1140 by gate valve 1135, and is isolated from atmospheric module (mini-environment) 1150 by gate valve 1196. An atmospheric track robot is provided inside the atmospheric module 1150. The atmospheric (ATM) robot has a base 1155 that rides on tracks 1170, and two independently controlled robot arms 1160 (e.g., SCARA) are mounted onto the base. Also, not shown in FIG. 11, but illustrated in FIG. 15, a set of storage shelves 1515 are also attached to the base 1155, such that the storage shelves are always at a static determined position with respect to the robot arms. The ATM robot exchanges wafers between the loadlock 1140 and FOUPs 1175. Note that in this example, lift pins 1185, 1190 and 1195 are provided in the processing chamber, the transfer chamber, and the loadlock, respectively. Thus, this particular embodiment utilizes two buffer stations: one in the transfer chamber and one in the mini environment in the form of the shelves attached to the ATM robot base.

An embodiment of the frog-leg robot can be further understood from FIG. 12, which is a cross section along lines A-A of FIG. 11. Enclosure 1280 is configured to maintain vacuum inside the transfer chamber. The two frog-leg robot arms are configured identically, but as mirror image of each other. Thus, description will be made for the right side in FIG. 12.

Motor 1205 is connected to timing pulley 1210, and via belts or chains to timing pulley 1215, timing pulley 1220, timing pulley 1225, and vacuum robot forearm 1230, so as to transmit rotational torque to the forearm. Motor 1235 is connected to timing pulley 1240, and via belts or chains to timing pulley 1245 and vacuum robot arm 1275 to transmit rotational torque to arm 1275. Exactly symmetrical mechanism is placed at the other side of the center line. Motor 1205 and motor 1235 are driven with certain coordination so that substrate hanger 1230 moves in linear motion or designated trajectory. Symmetrical side mechanism follows exactly mirror imaged motion as the primary side, or it may move slightly more or slightly less to time adjust the skew of the hanger. Vacuum robot arm 1275 is equipped with hollow cavity where all motion mechanism are captured and isolated from vacuum environment by vacuum seal 1250 to keep the environment particle free. Substrate hanger 1230 has two layers of substrate hangers 131a and 131b, i.e., it is referred to herein as a double-decker hanger. Substrate lifter has lifting pins 1290 that can lift substrates at both lower layer 131b and upper layer 131a to transfer from and to substrate hanger 1230. Substrate lifter pins 1290 are connected to lifter shaft 1265, and to lifter actuator 1270.

When actuated, motor 1205 rotates timing pulley 1210, which in turn rotates timing pulley 1215. Pulley 1215 is attached to pulley 1220 via a shaft, which is secured by two ball bearings 1255, and pulley 1220 transfers the rotation to pulley 1225. This action provides the mechanized controlled rotation of forearm 1138 about the elbow 1136, as shown in FIG. 11. Motor 1235 rotates timing pulley 1240, which in turn rotates timing pulley 1245, to thereby rotate the arm 1275 of the frog-leg robot. This action provides the mechanized controlled rotation of arm 1134 about the shoulder 1132, as shown in FIG. 11. The wrist connection to hanger 1230 is done via ball bearing 1256, such that it freely rotates without mechanized motor. Thus, no motor or synchronization means are necessary, and no motive force is applied at the wrist.

Also shown in FIG. 12 is the wafer lifter that may also serve as buffer station. The lifter has a substrate lifter shaft 1265, that is movable vertically by substrate lifter actuator 1270. The wafers are supported by lift pins 1190, also shown in FIG. 11.

Another feature that acts as a buffer station is the double-decker hanger 1230. The double-decker hanger 1230 may be used in any of the embodiments described herein, and conversely the single-decker hanger shown in FIGS. 6 and 6B may be used in any of the embodiments described herein, including that of FIGS. 11 and 12. However, as will be described in more details below, the use of a double-decker hanger 1230 provides increased processing time during each cycle of wafer exchange. Therefore, in application where processing time is relatively long, a single-decker hanger may be used, while in applications where processing time is relatively short, such that wafer exchange is a bottleneck, then a double-decker hanger may be used to reduce the time for wafer exchange with the processing chamber. In applications utilizing double-decker hanger 1230 it is beneficial to designate a single utility for each level of the double-decker hanger. For example, in the embodiment of FIG. 12, the upper level, 131a is configured to always deliver wafers, while the lower level 131b is configured for always remove wafers. This benefit will be explained below with respect to FIGS. 19-1 to 19-18, as compared to FIGS. 18-1 to 18-12.

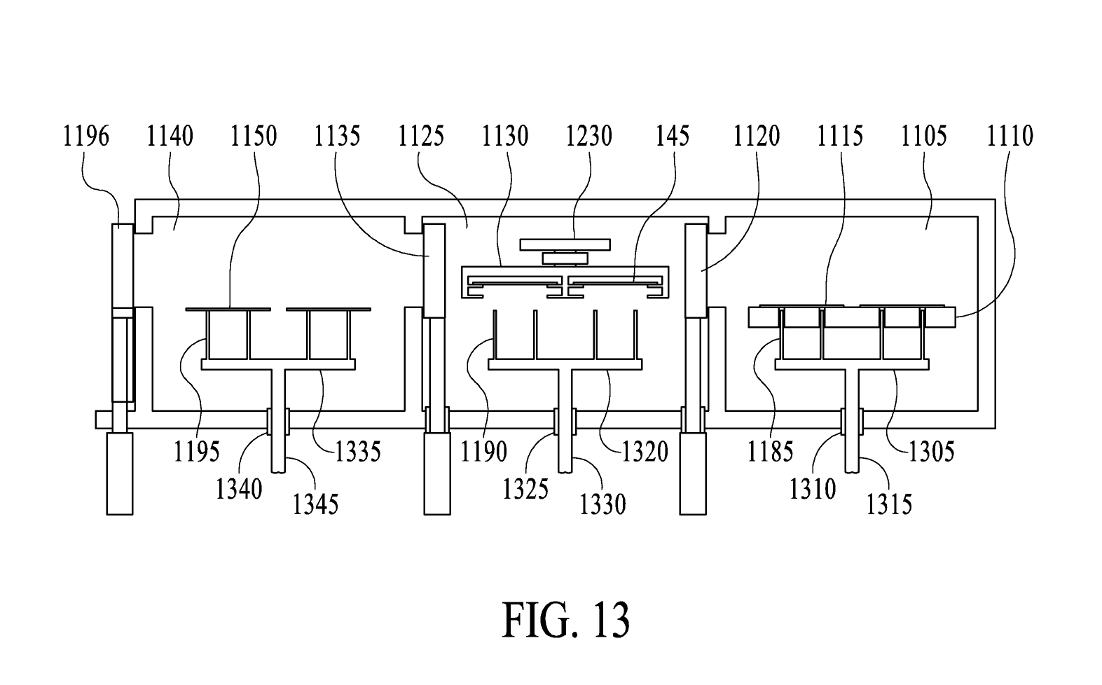

FIG. 13 illustrates a cross-section along line B-B in FIG. 11. This view shows the processing chamber 1105, transfer chamber 1125, and loadlock 1140. In the process chamber 1105, substrate lifting pins 1185 are connected to lifting pin plate 1305 and to lifting shaft 1315 via vacuum seal 1310, then to actuator which is not shown in FIG. 13. Process chamber substrate lifting pins 1185 can transfer substrate 1115 to both lower layer 131b and upper layer 131a of the substrate hanger 1130 by moving to preprogrammed respective level. When substrate lifting pins 1185 move to the lowest position, substrates 1115 are placed on process stage or susceptor 1110. In the transfer chamber 1125, substrate lifting pins 1190 are connected to lifting pin plate 1320 and to lifting shaft 1330 via vacuum seal 1325, then to actuator which is not shown in FIG. 13. Transfer chamber substrate lifting pins 1190 can transfer substrates to both lower layer 131b and upper layer 131a of the substrate hanger 1130 by moving to the appropriate level. When substrate lifting pins 1190 move to the lowest position, the substrate are placed lower than substrate hanger 1130 passage, thereby enabling the hanger to pass above without colliding with the substrates in their buffer position. In the loadlock chamber 1140, substrate lifting pins 1195 are connected to lifting pin plate 1335 and to lifting shaft 1345 via vacuum seal 1340, then to actuator which is not shown in FIG. 13. Loadlock chamber substrate lifting pins 1195 can transfer substrates to both lower layer 131b and upper layer 131a of the substrate hanger 1130 by moving to the appropriate level. When loadlock lifting pins 1195 move to the lowest position, the substrates 1150 are placed lower than substrate hanger 130 passage.

In the instance of time shown in FIG. 13, all gate valves 1120, 1135, and 1196 are closed, such that the environments in each of the chambers is isolated from the other chambers. Also, in the instance of time shown, wafers 1115 are on the susceptor 1110 for processing, wafers 145 are on the upper level of the double decker hanger 1130, and wafers 1150 are on lift pins 1195 in the loadlock. Such a position occurs twice in each cycle, once just after delivering fresh wafers to the processing chamber and once just prior to the processing chamber completing processing the wafers.

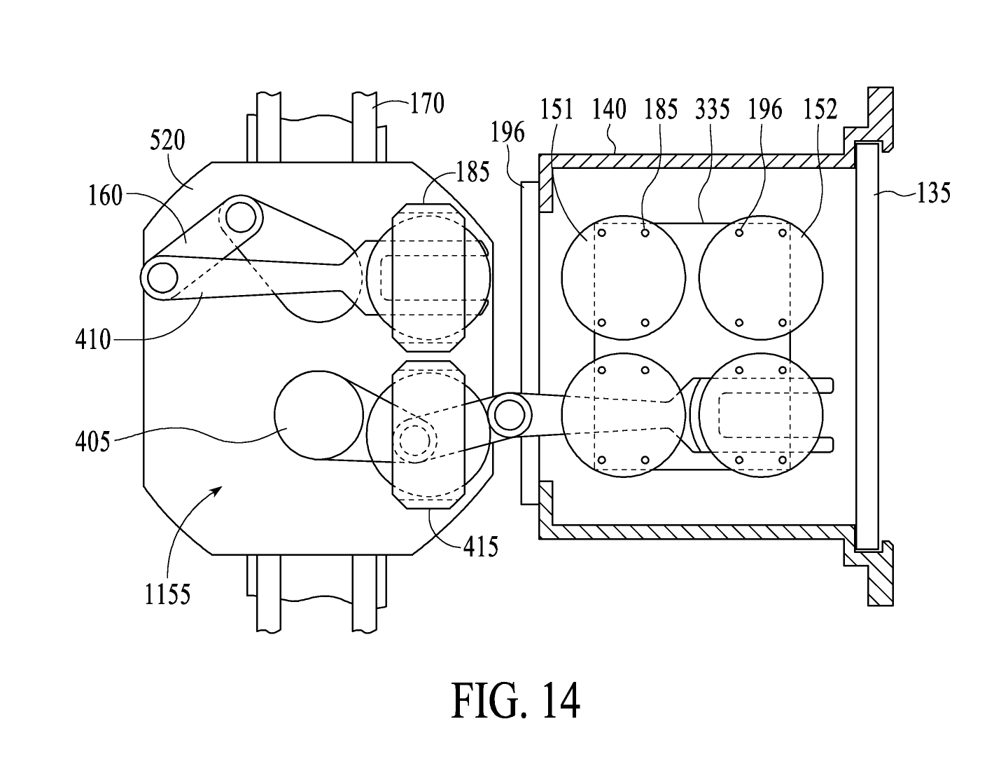

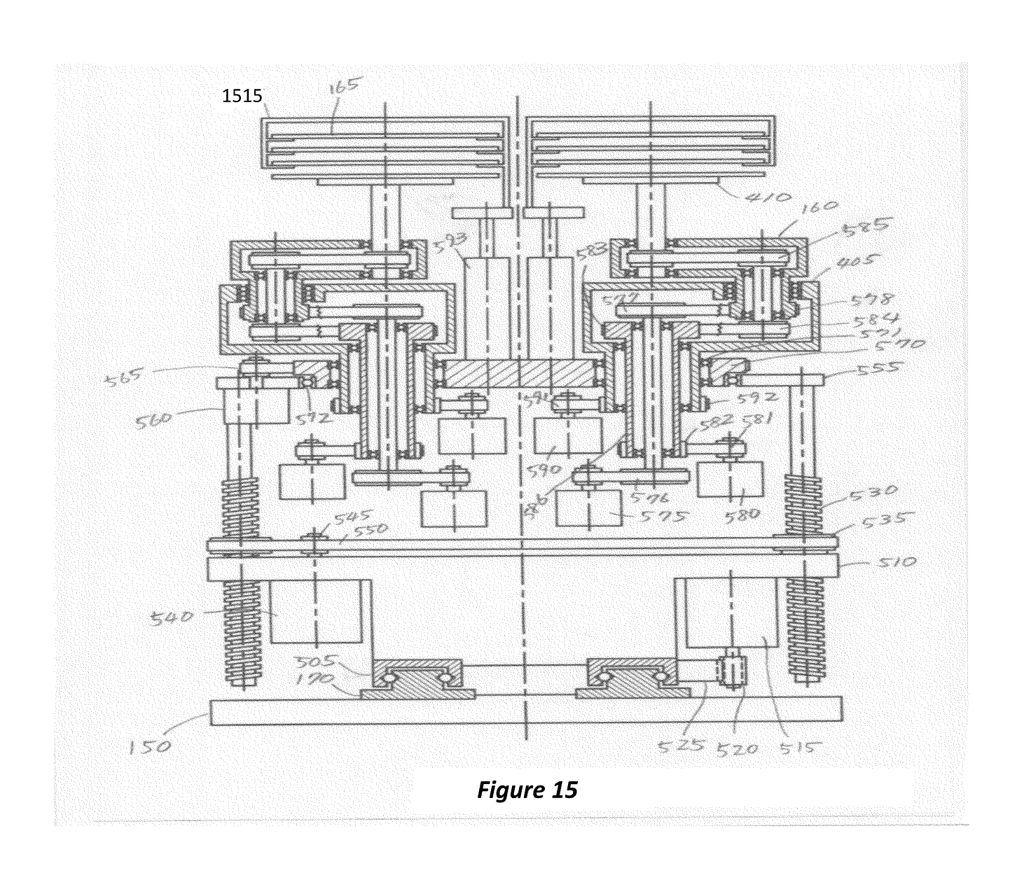

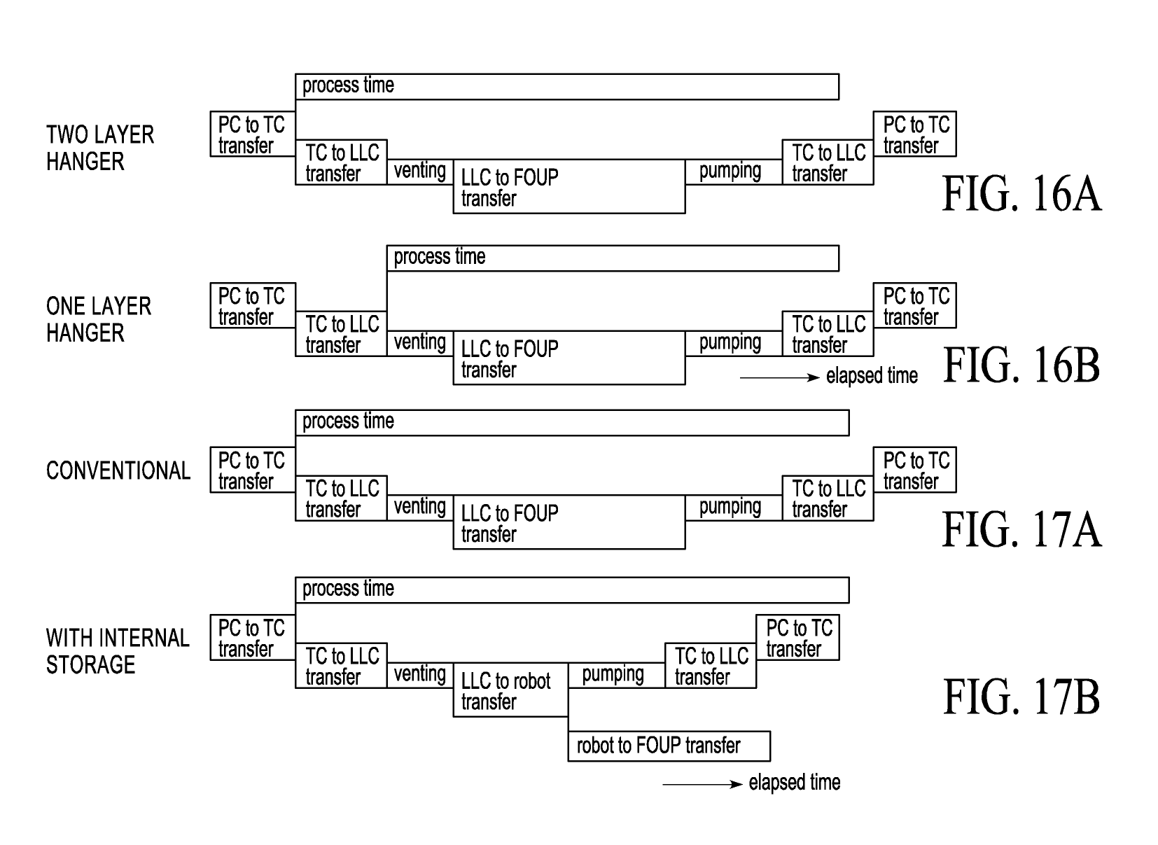

FIG. 14 illustrates a top view of the ATM robot arrangement 570 together with the loadlock 140. ATM robot 570 has a base 1155 that rides on tracks 170. Two robot arms 160, e.g., SCARA, are attached to the base 570 side-by-side. Also attached to the base is shelves arrangement 415 having wafer storage shelves stacked vertically in two rows. Note that the shelves are affixed to the base, so that they move together with the ATM robot on tracks 170. Each robot arm 160 together with its end effector 410, are configured for reaching two wafer positioned in one row inside the loadlock 140. Thus, robot arm 160 can reach the positions of wafers 151 and 152 illustrated inside loadlock 140.

The ATM robot end effector 410 is attached to ATM robot forearm 405. Substrate 165 is placed on top of the end effector 410. Two symmetrical ATM robots are placed on timing pulley/robot rotary base 570. Each of the symmetrical robots can move independently to transfer substrates from and to FOUP 1175 to substrate storage shelves 415, and from and to substrate storage shelves 415 to wafer lifting pins 195 or 196 corresponding to substrate 150 and 151. The ATM robot end effector 410 moves linearly as well as in designated trajectory.

The arrangement of the ATM robot and storage shelves can be further understood from FIG. 15, which is a cross-section along lines C-C of FIG. 11. The ATM robot module has base 150 which rides on two track rails 170, using linear slides 505. A motor 515 is attached to atmospheric module base 150. Pinion gear 520 is attached to the motor 515 and rack gear 525 is attached to robot slide base 510. The motor 515 moves slide base 510 linearly between FOUPs 1175 and loadlock chambers 1140 (FIG. 11). On slide base 510, jack screws 530 are attached. Motor 540 is attached to slide base 510 and transmits torque to timing pulley 545 and timing belt 550 to both jack screws through nut 535. Elevator base 555 is attached to jack screws 530, such that the motor 540 can move elevator base 555 vertically to the position where the end effector can transfer substrate from and to FOUP to loadlock chamber 140. On elevator base 555, robot rotary base/timing pulley 570 is connected via ball bearings 572. By transmitting torque from motor 560 and timing belt 565, robot rotary base rotates with respect to elevator base 555. On robot rotary base 570, two ATM robots 160 and two storage shelves 415 are mounted. Thus, the two ATM robots 160 and two storage shelves 415 move linearly with the slide base 510.

Motor 590 is mounted on rotary base 570. Motor 590 transmit torque to timing pulley 591 and timing pulley 592 to robot upper arm 405. Motor 580 is mounted on rotary base 570. Motor 580 transmit torque to timing pulley 581 to timing pulley 582 to timing pulley 583 to timing pulley 584 to timing pulley 585 to end effector 410. Motor 575 is mounted on rotary base 570, or can be mounted on shaft 586. Motor 575 transmit torque to timing belt 576 to timing belt 577 to timing pulley 578 to forearm 160. By coordinating motion of motors 575 and 580 end effector 410 move in linear motion or in designated trajectory. By coordinating motion of motors 590 and 575 and 580, end effector and upper arm and lower arm assembly as a whole rotate on ball bearing 571. Rotation of assembly on ball bearing 571 is normally used to make fine adjustment of substrate placement on the lift pins 151 or 152 in the loadlock chamber 140. Storage shelves 415 are connected to storage shelves actuator 593 and have at least 2 substrate storing capacity on each side. Storage shelves actuator 593 moves vertically to move storage shelves to transfer substrate from and to end effector to each of the shelves. Thus, the shelves can be linearly moved with the robot arms, and vertically stepped to different vertical elevations with respect to the robot arms. This enables the ATM robot to serve the loadlock at higher efficiency and speed without the need to repeatedly turn to deliver or retrieve wafers from the FOUPs. Rather, wafer exchange with the FOUPs can be performed when the loadlock is under vacuum pumping, such that the loadlock is not starved for wafers.

FIGS. 16A and 16B are graphical time-charts illustrating the timing difference between having a double-decker hanger (FIG. 16A) and a single level hanger (FIG. 16B). As shown in FIG. 16A, processing inside processing chamber may start earlier in the cycle, as opposed to the cycle of FIG. 16A. This is because in FIG. 16A the robot with the double-decker hanger exchanges the wafers between the processing chamber and the transfer chamber, and then the chamber gate valve may be closed and processing may commence. The processed wafers that are in the transfer chamber may then be delivered and exchanged with fresh wafers from the loadlock. Conversely, when having only a single level hanger, the wafers must be exchanged between the transfer and the loadlock before the gate valve of the processing chamber may be closed and processing commence. That is, in embodiments using one layer hanger system, substrate load and unload sequence reciprocates between process chamber and loadlock chamber via transfer chamber, and process task inside the process chamber cannot start until all load unload sequence completes. On the other hand, in two layer hanger, substrate load and unload sequence is divided to two sequences: one is transfer between process chamber and transfer chamber, the other is transfer between transfer chamber and loadlock chamber. In this sequence, after process chamber to transfer chamber sequence is finished, process task inside the processing chamber can start, while the transfer chamber to loadlock chamber sequence runs in parallel. Therefore, for the same tact time, process time will be longer and higher efficiency is obtained.

Using the embodiment having the internal storage, i.e., shelves incorporated into the ATM robot, also helps in reducing idle time of the processing chamber. This can be seen when comparing the timing charts of FIGS. 17A and 17B. In conventional system, atmospheric substrate transfer sequence reciprocates between loadlock chamber and FOUP via ATM robot, and the loadlock task cannot start the pumping down sequence until all load and unload sequence completes. On the other hand, using the embodiments where the ATM robot has internal storage capability, the sequence is divided into two: one is transfer between loadlock chamber and internal storage on the ATM robot, the other is internal storage to FOUP. In this sequence, loadlock chamber can start pumping down immediately after the loadlock to internal storage transfer task is completed. Therefore, the total tact time will be reduced by the amount of time to transfer between internal storage to FOUP, and it increases total throughput.

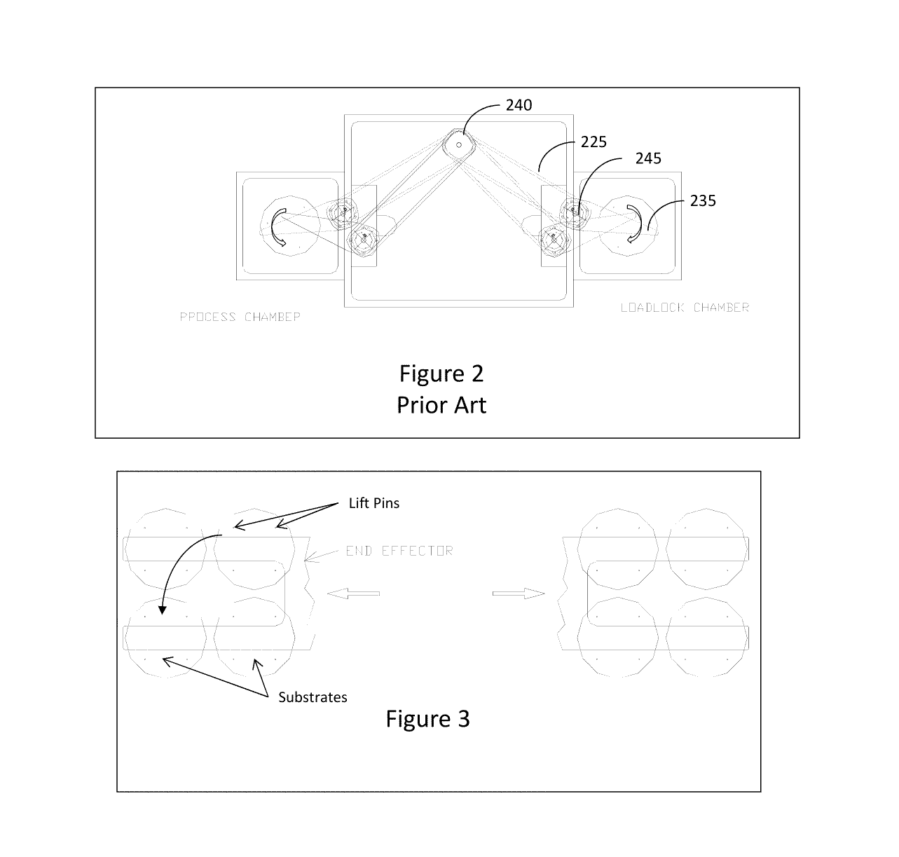

We now turn to FIGS. 18-1 to 18-13, illustrating the sequence for wafer exchange in an embodiment having a single-level hanger. This same sequence can be performed by any of the robots of the embodiments described above. In FIG. 18-1, processing of wafers 1815 has just completed inside process chamber 1805. Previously, fresh wafers 1845 have been loaded and placed in the buffer station in transfer chamber 1825. No wafers are present in loadlock chamber 1840, and all gate valves, 1820, 1835 and 1896 are closed. Robot 1830 has empty hanger inside the transfer chamber 1825. In FIG. 18-2, gate valves 1820 and 1835 have been opened to start the wafer exchange. Also, lift pins 1885 inside the process chamber 1805 have been raised so as to lift processed wafers 1815 from the susceptor 1810.

In FIG. 18-3 robot 1830 has moved the empty hanger into the processing chamber to remove the processed wafers 1815. In FIG. 18-4 the lift pins 1885 have been lowered, so that the wafers hang on the hanger of robot 1830. Then, in 18-5, the robot 1830 moves the processed wafers 1815 into the loadlock 1840. During this move the lift pins 1890 are in their low position, so that the robot can move the hanger over the fresh wafers 1845 without collision. In 18-6 the lift pins 1895 have been raised to remove the processed wafers from the hanger, while the lift pins 1890 have been raised to prepare the fresh wafers 1845 to be picked up by the robot 1830. In 18-7 robot 1830 has dropped the processed wafers 1815 on lift pins 1895 inside the loadlock 1840 and has moved to the transfer chamber to collect fresh wafers 1845. In 18-8 lift pins 1890 have lowered to leave the fresh wafers 1845 hanging on the hanger. At the same time, gate valve 1835 has been closed so that the ATM robot (not shown here) can remove the processed wafers 1815 and deliver a new batch of fresh wafers into loadlock 1840.

In 18-9 the robot 1830 moved into processing chamber to deliver the fresh wafer 1845. Meanwhile, ATM robot has removed the processed wafers from the loadlock. In 18-10 lift pins 1885 are raised to remove the fresh wafers 1845 from the hanger. In 18-11 the robot 1830 moves the hanger back into the transfer chamber 1825 and leaves the fresh wafers 1845 on lift pins 1885. Then in 18-12 gate valve 1820 and pumping and processing in the processing chamber 1805 can commence. The lift pins 1885 are in their lower position, so that the wafers 1845 are placed on the susceptor. At the same time, a new batch of fresh wafers 1847 has been loaded into the loadlock 1840 by the ATM robot (not shown). The cycle may now repeat.

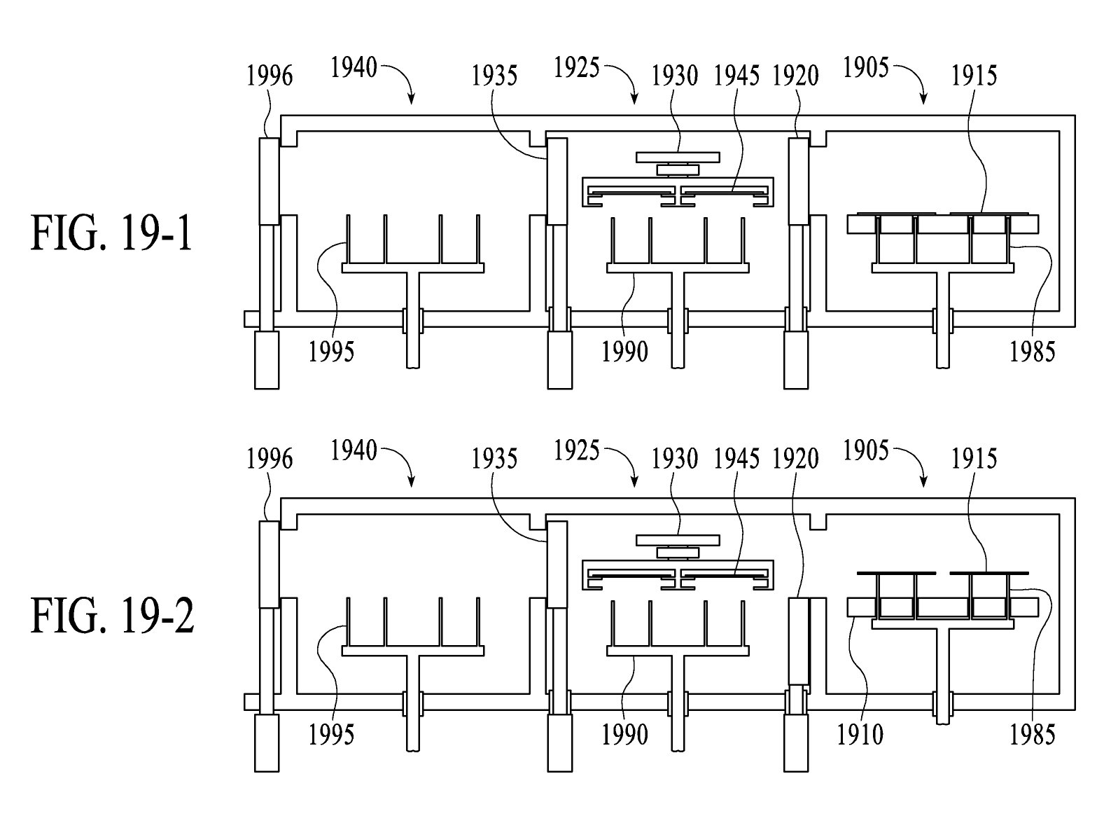

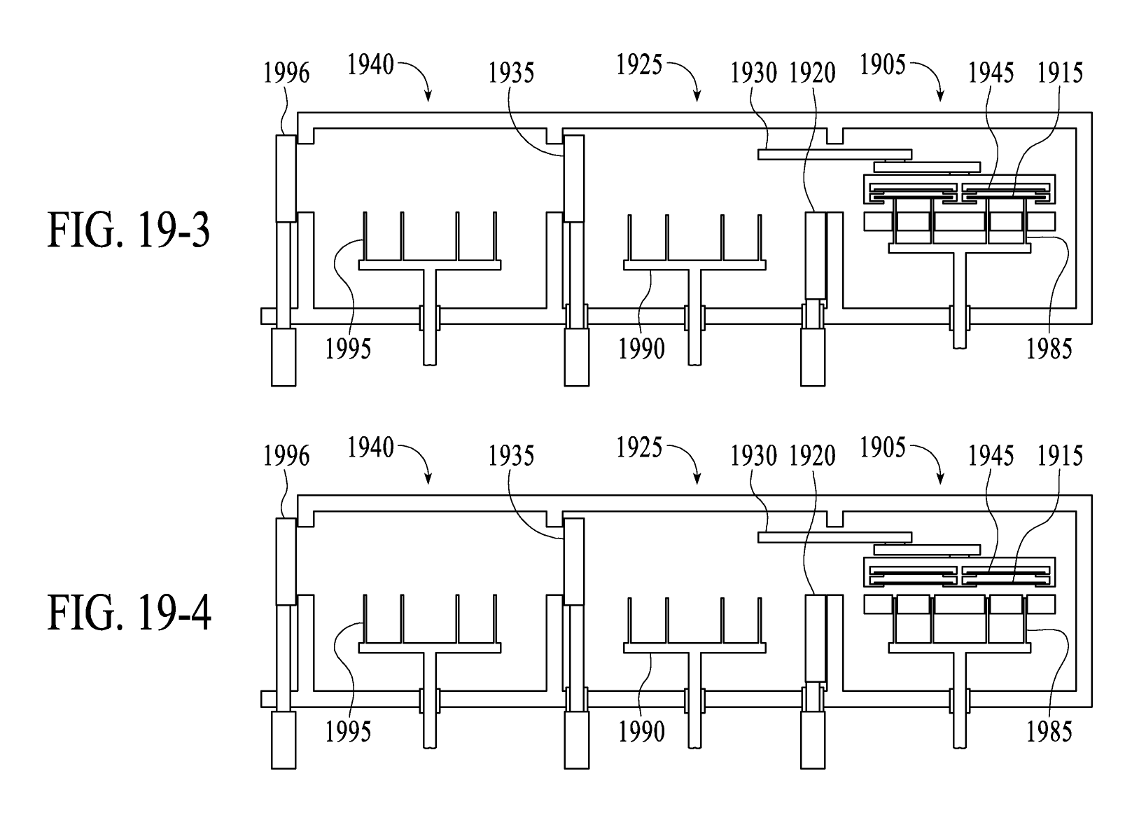

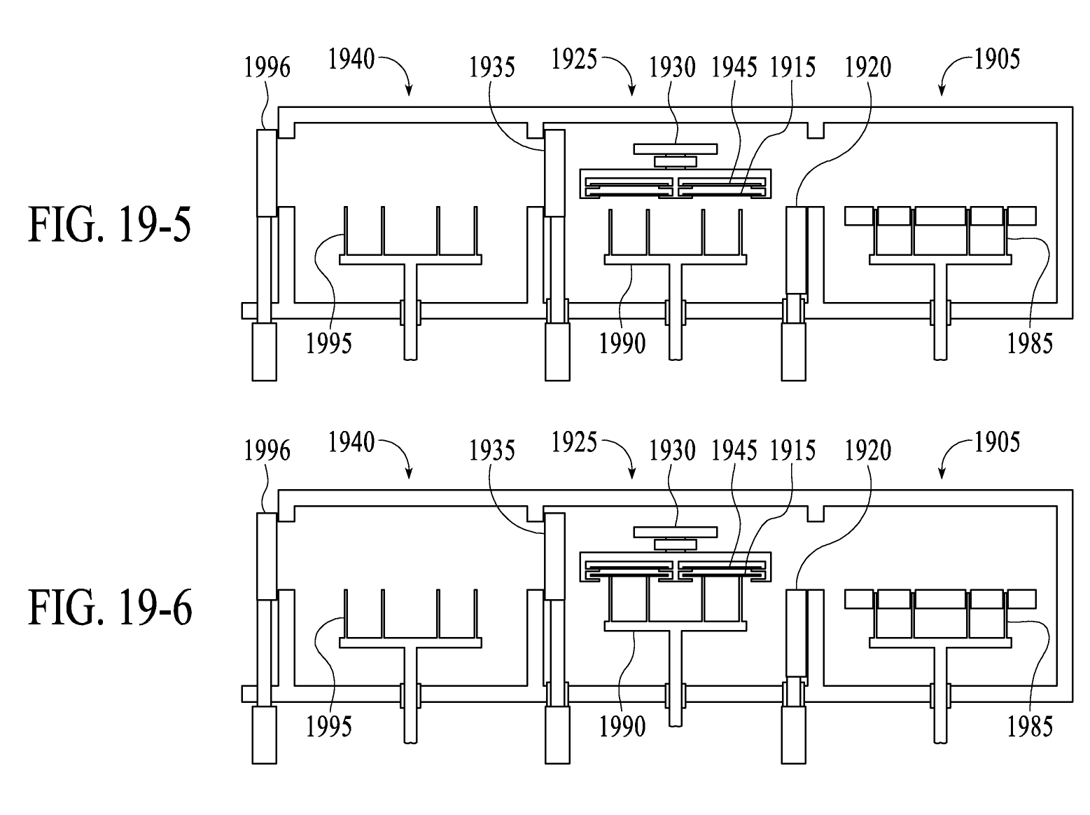

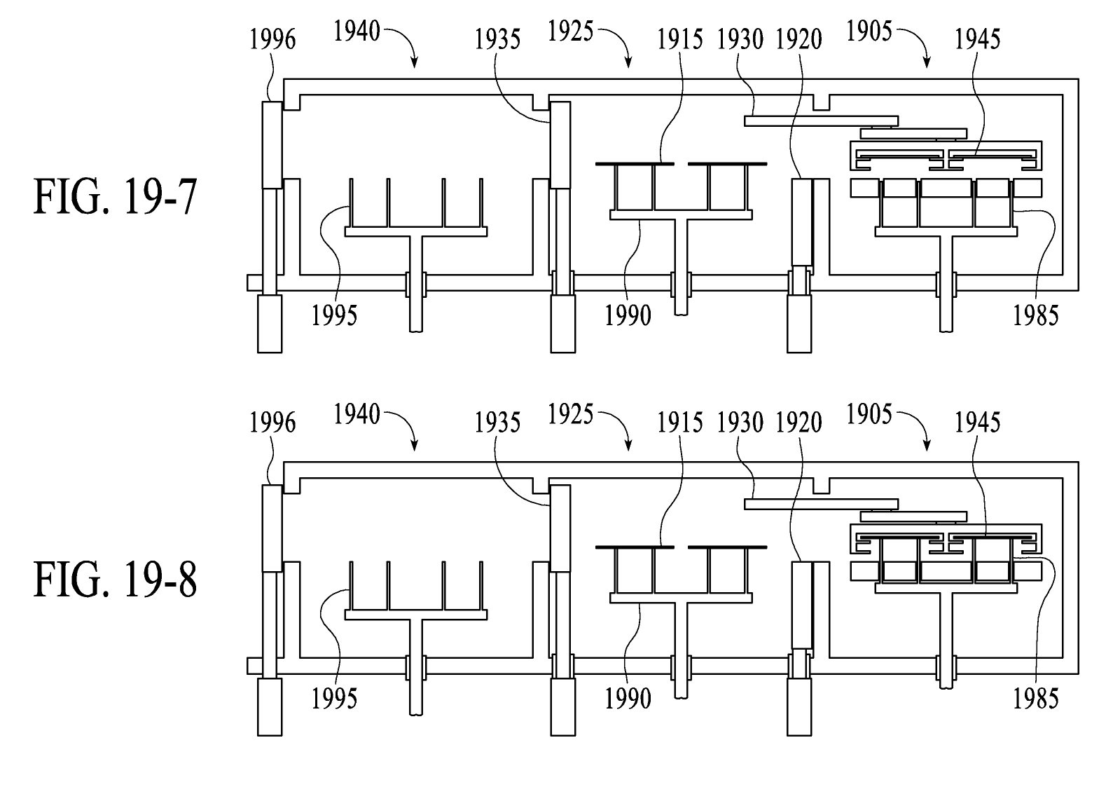

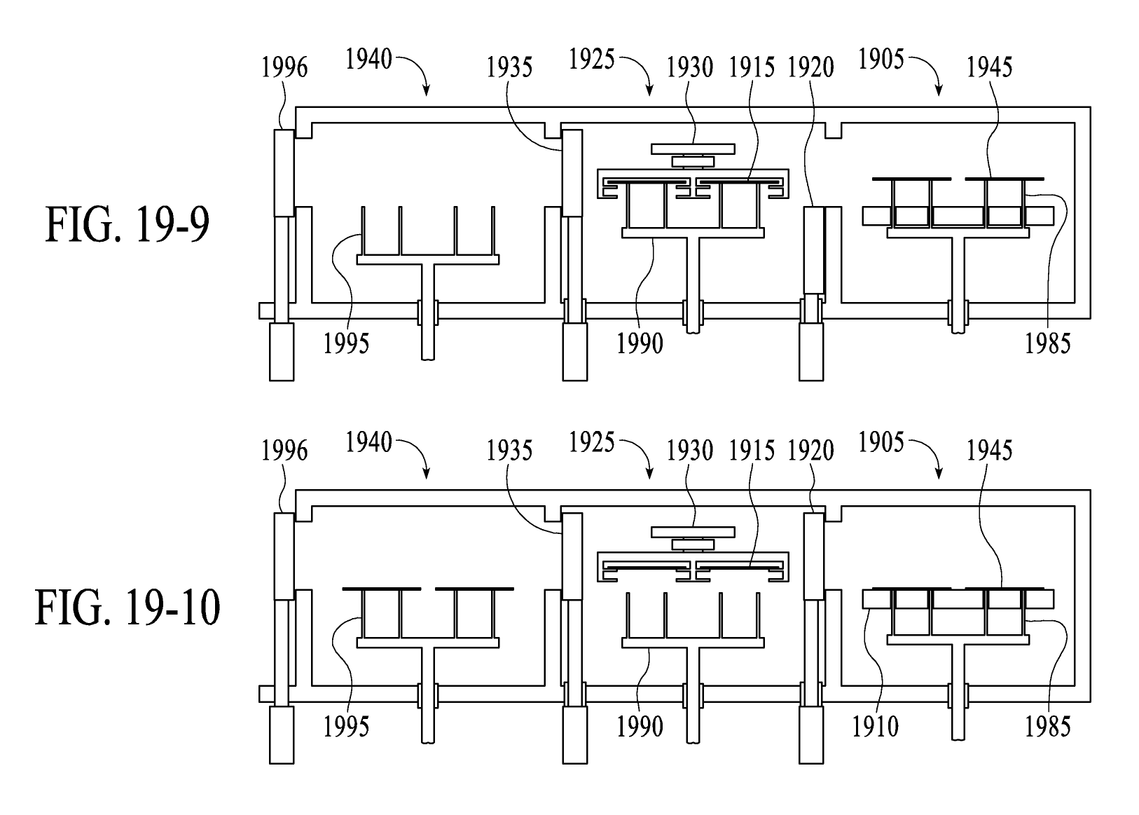

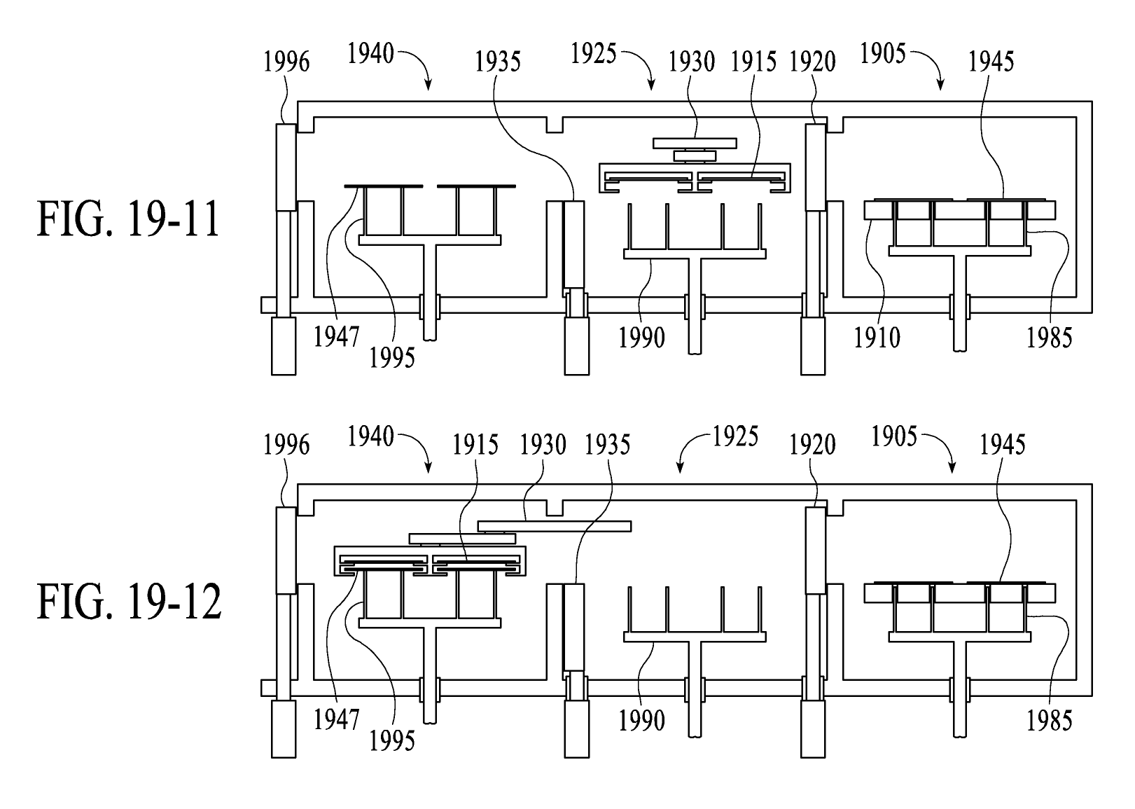

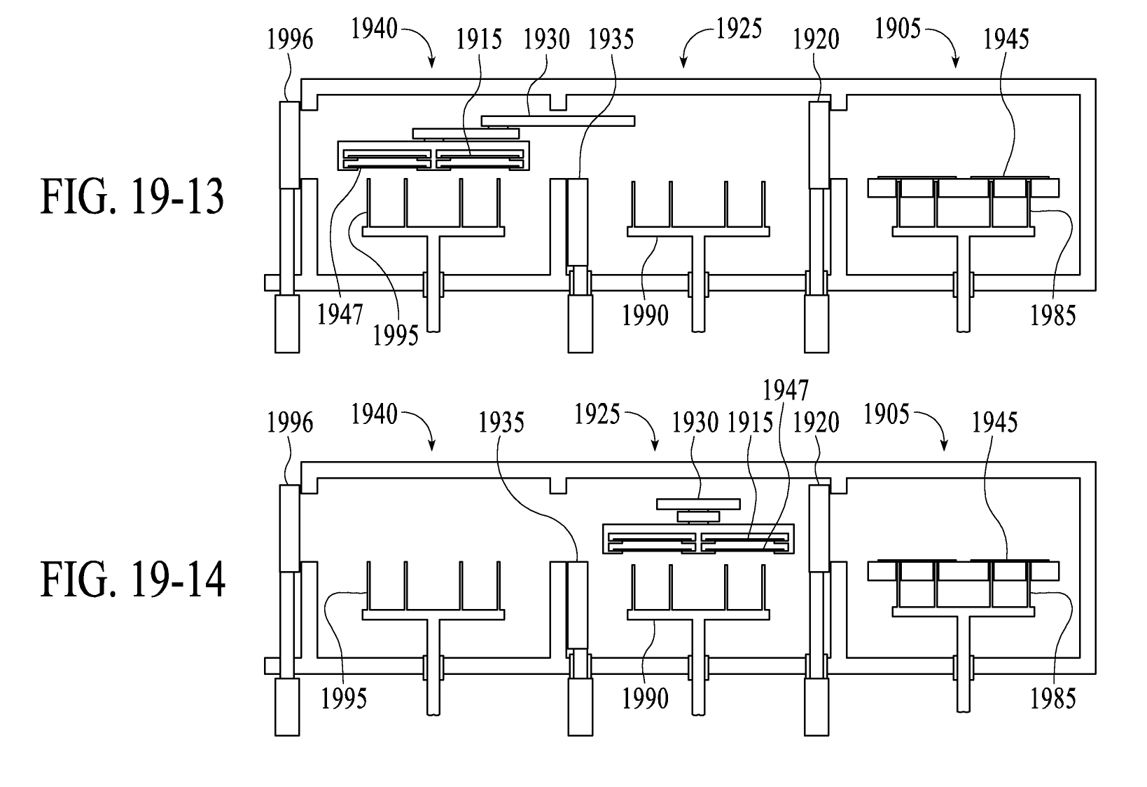

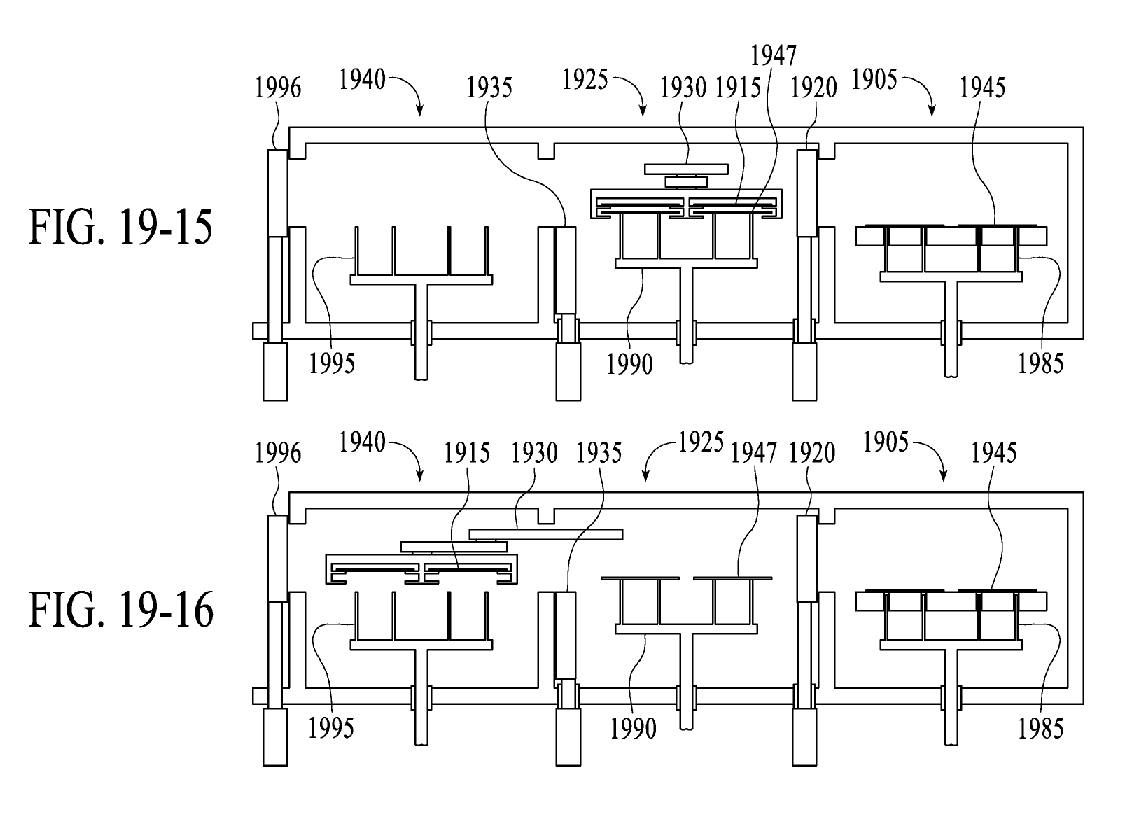

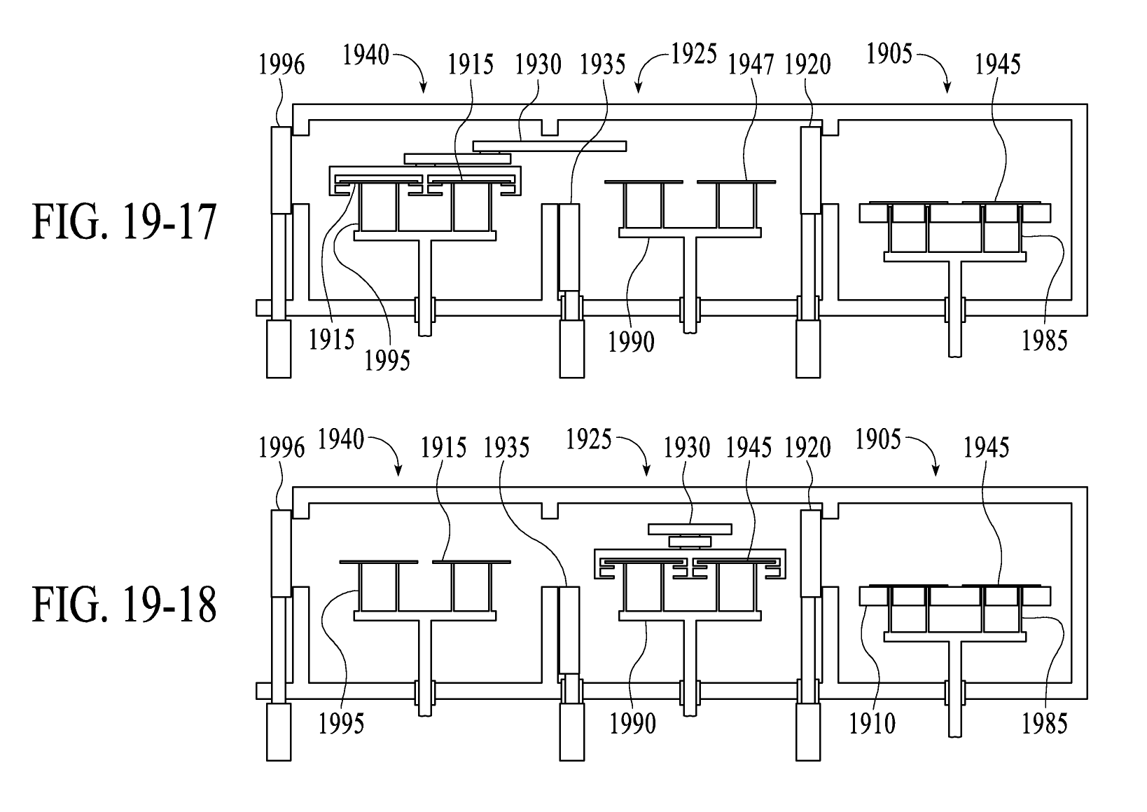

The sequence for wafer exchange in an embodiment using a double-decker hanger will now be described with reference to FIGS. 19-1 to 19-18. This same sequence can be performed by any of the robots of the embodiments described above, wherein a double-decker hanger is attached to the robot. In FIG. 19-1, processing of wafers 1915 has just completed inside process chamber 1905. Previously, fresh wafers 1945 have been loaded and placed on the top level shelves of the hanger of robot 1930 inside transfer chamber 1925. No wafers are present in loadlock chamber 1940, and all gate valves, 1920, 1935 and 1996 are closed. Robot 1930 has its lower level shelves of the hanger empty.

In FIG. 19-2, gate valve 1920 has been opened to start the wafer exchange. Also, lift pins 1985 inside the process chamber 1905 have been raised so as to the lift processed wafers 1915 from the susceptor 1910. Note that in this embodiment, wafer exchange for the processing chamber is performed with the valve gates 1935 of loadlock chamber 1940 closed. In 19-3 robot 1930 moves the hanger into the processing chamber so as to collect the processed wafers 1915 on the lower level shelves. Then in 19-4 the lift pins 1985 are lowered, such that the processed wafers are deposited on the lower level shelves of the hanger.

In 19-5 the robot 1930 moves the hanger to the transfer chamber 1925 to deposit the processed wafers 1915 in the buffer lift pins 1990. In 19-6 lift pins 1990 are raised to collect the processed wafers 1915 from the lower level hanger. In 19-7 the robot 1930 again transfer the hanger into the processing chamber and in 19-8 the lift pins 1985 are raised to remove the fresh wafers 1945 from the upper level shelves of the hanger. In 19-9 the robot 1930 returns the hanger to the transfer chamber to re-collect the processed wafers 1915 onto the upper level shelves. Then in 19-10 lift pins 1990 are lowered to deposit processed wafers 1915 onto the upper level shelves of the hanger, gate valve 1920 is closed, and lift pins 1985 are lowered to deposit fresh wafers 1945 onto the susceptor for processing. At this point pumping and processing inside processing chamber 1905 may begin. Meanwhile, as shown in 9-10, ATM robot has placed a new batch of fresh wafers 1947 on lift pins inside the loadlock 1940.

As the processing in processing chamber 1905 progresses, the processed wafers 1915 are exchanged with the new batch of fresh wafers 1947, as shown in FIGS. 19-11 to 19-18. In 19-11 gate valve 1935 to the loadlock has been opened, and in 19-12 the robot 1930 enters the loadlock 1940 to collect the new batch of wafers 1947 onto the lower level shelves of the hanger. In 19-13 lift pins 1995 have been lowered, thereby placing the fresh wafers 1947 on the bottom shelves of the hanger. In 19-14 the robot 1930 has been retrieved into transfer chamber 1925 to deposit the fresh wafers 1947. In 1915 lift pins 1990 have been raised to remove fresh wafers 1947 from the hanger, and in 19-16 robot 1930 enters the loadlock 1940 to deposit the processed wafers 1915. Fresh wafers 1947 remain on lift pins 1990. In 19-17 lift pins 1995 are raised to remove processed wafers 1915 from the hanger, and in 19-18 the processed wafers 1915 remain on lift pins 1995, while robot 1930 returns to transfer chamber 1925 to collect fresh wafers 1947 from lift pins 1990. Gate valve 1935 is then closed, lift pins 1990 are lowered, and ATM robot removes wafers 1915 from the transfer chamber 1940. The system then returns to the condition illustrated in 19-1.

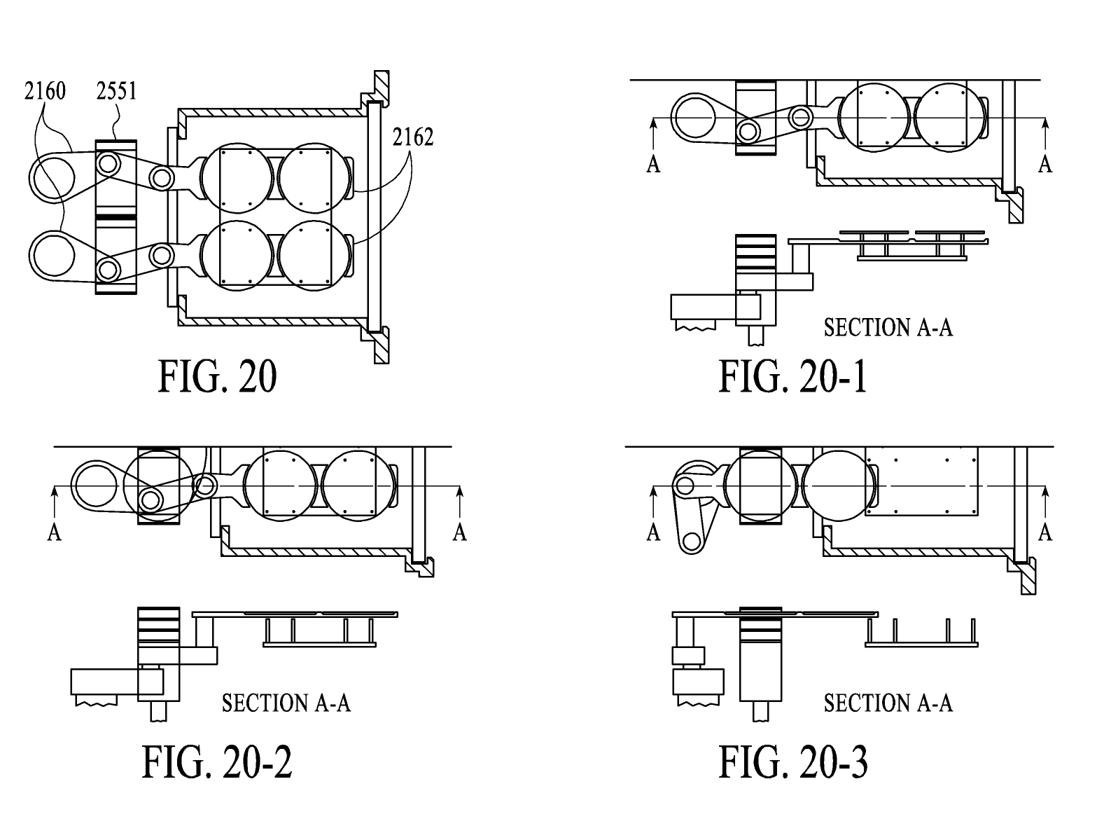

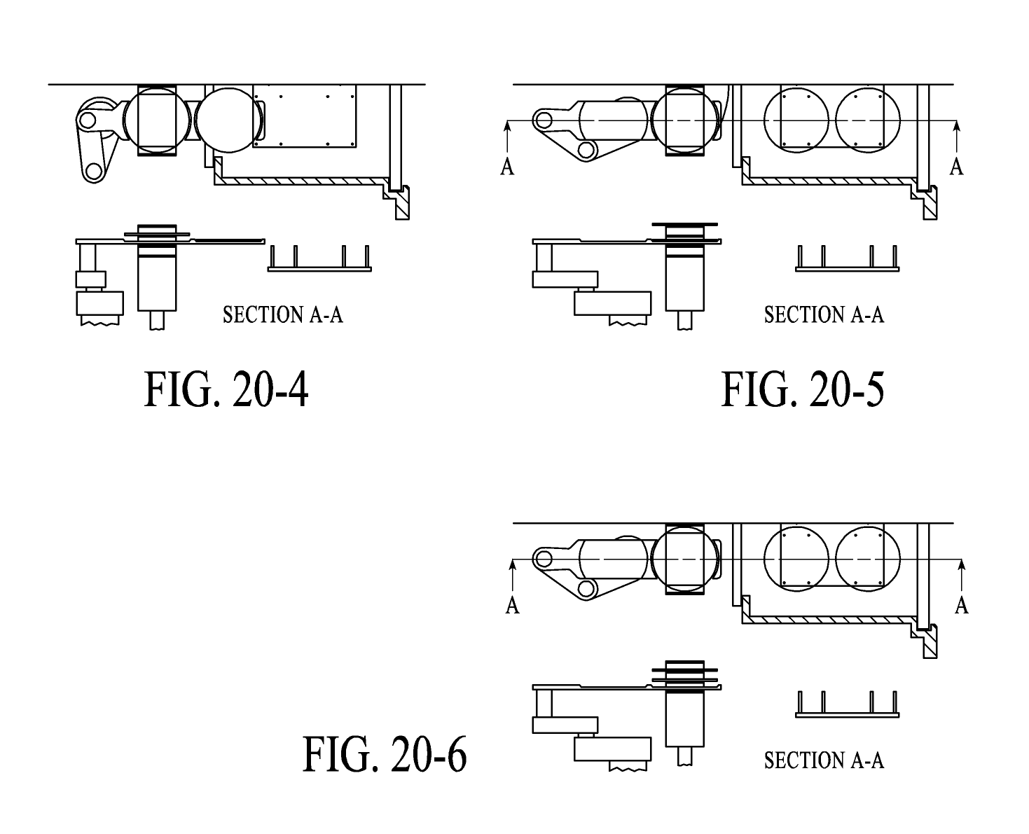

FIG. 20 illustrates another embodiment of the atmospheric robot with storage shelves, while FIGS. 20-1 to 20-6 illustrate operation of the ATM robot. In FIG. 20, two robot arms 2160, e.g., SCARA, are attached to the base side-by-side. Each of the two robot arms 2160 has an end effector 2162 that is configured to have two pockets to hold two wafers in a row, one behind the other. One pocket is provided at the tip of the end effector and one at the base of the end effector. Each end effector 2162 is configured such that the distance between the two pockets is the same as the distance of the wafers when positioned inside the loadlock chamber. The storage shelves 2515 are also attached to the base, as in the previous embodiments.

By following the step shown in FIGS. 20-1 through 20-6, transfer of the wafers from the loadlock to storage 2515 is done in 6 steps, whereas it takes 8 steps for the single pocket end effector. By reversing the steps 20-1 through 20-6, transfer of the wafers from the storage to loadlock is also done in 6 steps. Wafer transfer to the FOUP is done using the pocket near the tip of the end effector.

In FIG. 20-1 the wafers are lifted up on the lift pins and the robot end effector is inserted under wafers. In FIG. 20-2 the lift pins are lowered and wafers rest on the two pockets of the end effectors. In FIG. 20-3 the robot retracts the end effector half way so that the pocket close to the base of the end effector is lined up with the storage shelf. In FIG. 20-4 the storage elevator indexes up and the wafer that rest in the pocket at the base of the end effector is lifted from the end effector onto one of the storage shelves. In FIG. 20-5 the robot further retracts the end effector so that the other pocket lines up with the storage shelf. In FIG. 20-6 the storage elevator indexes up and the wafer positioned in the pocket at the tip of the end effector is lifted onto the next storage shelf below the first one.

It should be understood that processes and techniques described herein are not inherently related to any particular apparatus and may be implemented by any suitable combination of components. Further, various types of general purpose devices may be used in accordance with the teachings described herein. The present invention has been described in relation to particular examples, which are intended in all respects to be illustrative rather than restrictive. Those skilled in the art will appreciate that many different combinations will be suitable for practicing the present invention.

Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

1. A substrate processing system, comprising:
a loadlock chamber having an entry slit and an exit slit positioned across from the entry slit;
a processing chamber having an entry slit;
a transfer chamber attached on one side to the loadlock chamber and on opposite side to the processing chamber, the transfer chamber having an entry slit overlapping the exit slit of the loadlock chamber, the transfer chamber further having exit slit overlapping the entry slit of the processing chamber;
a first gate valve provided to selectively seal the entry slit of the loadlock chamber;
a second gate valve provided to selectively seal the exit slit of the loadlock chamber;
a third gate valve provided to selectively seal the entry slit of the processing chamber;
a transfer robot provided inside the transfer chamber, the transfer robot comprising a substrate hanger configured for holding a plurality of substrates simultaneously, the transfer robot configured to exchange substrates between the loadlock chamber and the processing chamber by linearly translating the substrate hanger without imparting any rotational motion to the substrate hanger.

2. The substrate processing system of claim 1, further comprising a lift pin arrangement situated inside the transfer chamber and configured for supporting a plurality of substrates simultaneously.

3. The substrate processing system of claim 1, further comprising:
an atmospheric chamber connected to the loadlock chamber and having a delivery port overlapping the entry slit of the loadlock chamber; and,
a track robot provided inside the atmospheric chamber and configured to exchange wafers with the loadlock chamber.

4. The substrate processing system of claim 3, further comprising:
a second loadlock chamber having an entry slit and an exit slit positioned across from the entry slit, the second loadlock chamber attached to the atmospheric chamber;
a second processing chamber having an entry slit;
a second transfer chamber attached on one side to the second loadlock chamber and on opposite side to the second processing chamber, the second transfer chamber having an entry slit overlapping the exit slit of the second loadlock chamber, the second transfer chamber further having exit slit overlapping the entry slit of the second processing chamber;
a second transfer robot provided inside the second transfer chamber, the second transfer robot comprising a second substrate hanger configured for holding a plurality of substrates simultaneously, the second transfer robot configured to exchange substrates between the second loadlock chamber and the second processing chamber by linearly translating the second substrate hanger without imparting any rotational motion to the second substrate hanger.

5. The substrate processing system of claim 3, further comprising:
a track robot arrangement positioned inside the atmospheric chamber and comprising:
linear tracks;
a base configured for linear motion on the linear tracks;
a first and a second articulated robot arms rotatably attached to the base side-by-side, each robot arm having an end effector attached to the end thereof;
substrate shelves arrangement attached to the base and positioned above the first and a second articulated robot arms.

6. The substrate processing system of claim 5, further comprising a stepper for vertically stepping the substrate shelves arrangement to different vertical elevations with respect to the first and a second articulated robot arms.

7. The substrate processing system of claim 1, wherein the transfer robot comprises:
an upper arm having a proximal end rotatably mounted onto a first pivot point;
a forearm having a proximal end rotatably mounted onto a second pivot point, the second pivot point configured onto distal end of the upper arm;
wherein the substrate hanger is rotatably mounted onto a third pivot point, the third pivot point configured onto distal end of the forearm, the substrate hanger configured for sliding over the substrates and having hanging extensions configured to slide under the substrates and hang the substrates from the periphery of each substrate, such that the substrates hang below the robot arm; and
wherein the upper arm, the forearm and the substrate hanger are coupled to electrical motors to be rotated independently but in coordination so as to impart linear transfer motion to the substrate hanger.

8. The substrate processing system of claim 7, wherein the substrate hanger is configured for lifting four substrates simultaneously.

9. The substrate processing system of claim 8, wherein the substrate hanger is symmetrical along an axis of symmetry passing through the third pivot point, the axis being orthogonal to the direction of the linear transfer motion.

10. The substrate processing system of claim 9, wherein the substrate hanger is mounted onto the third pivot point at the bottom of the distal end of the forearm thereby hanging below the forearm.

11. The substrate processing system of claim 1, wherein the substrate hanger is configured for sliding over the substrates and having hanging extensions configured to slide under the substrates and hang the substrates from the periphery of each substrate, such that the substrates hang below the substrate hanger.

12. The substrate processing system of claim 1, wherein the transfer robot comprises a frog-leg robot arrangement for transferring flat substrates, comprising:
a first and a second frog-leg arms having identical structure;
wherein each of the first and second frog-leg arms comprises:
an upper arm rotatably mounted at its proximal end onto a base, the upper arm being coupled to a first motor to impart rotational torque to the upper arm;
a forearm rotatably mounted at its proximal end onto distal end of the upper arm, the forearm being coupled to a second motor to impart rotational torque to the forearm independently of rotation of the upper arm;
a freely rotatable wrist positioned at the distal end of the forearm and rotatably connected to one of two pivotal points provided on top of the substrate hanger.

13. The substrate processing system of claim 12, wherein the substrate hanger comprises a plurality of hanging extensions configured to slide under the substrates and hang the substrates from the periphery of each substrates.

14. The substrate processing system of claim 13, wherein the plurality of hanging extensions are provided on two vertical levels, such that two sets of substrates can be supported by the substrate hanger, one above the other.

15. The substrate processing system of claim 13, further comprising:
a first set of lift pins provided inside the loadlock chamber;
a second set of lift pins provided inside the transfer chamber;
a first set of lift pins provided inside the processing chamber.

16. The substrate processing system of claim 15, wherein each of the first second and third sets of lift pins is configured for lifting four substrates simultaneously.

17. The substrate processing system of claim 1, wherein the hanger is attached to the transfer robot using two feely rotatable pivot connections.

18. The substrate processing system of claim 1, wherein the hanger is attached to the transfer robot using one motorized rotatable pivot connection.

19. The substrate processing system of claim 12, wherein the first and second frog-leg arms are configured to translate the hanger in a linear motion over the base.

20. The substrate processing system of claim 5, wherein each of the first and second articulated robot arms comprises an end effector having two pockets to hold two wafers in a row one behind the other.
